(19) United States
(12) Patent Application Publication
(10) Pub. No.: US 2025/0001740 A1
(43) Pub. Date: Jan. 2, 2025

(54) LAMINATED FILM HAVING IMPROVED SURFACE HARDNESS AND RESTORATION PROPERTIES AND DISPLAY DEVICE COMPRISING SAME

(71) Applicants: SK MICROWORKS SOLUTIONS CO., LTD., Chungcheongnam-do (KR); SK MICROWORKS CO., LTD., Gyeonggi-do (KR)

(72) Inventors: Hyung-Woo CHO, Chungcheongnam-do (KR); Seok-Jong WOO, Chungcheongnam-do (KR); Jun-Ki PARK, Chungcheongnam-do (KR); Kweon Hyung HAN, Gyeonggi-do (KR); Kwangho JANG, Gyeonggi-do (KR)

(21) Appl. No.: 18/292,930

(22) PCT Filed: Jul. 6, 2022
(86) PCT No.: PCT/KR2022/009742

§ 371 Date: Jan. 29, 2024

(30) Foreign Application Priority Data
Jul. 30, 2021 (KR) 10-2021-0101035
Jul. 30, 2021 (KR) 10-2021-0101037

(51) Int. Cl. B32B 27/08; B32B 7/12; B32B 27/28; B32B 27/34; B32B 27/36; H10K 59/80; H10K 77/10; H10K 102/00

(52) U.S. Cl. CPC B32B 27/08; B32B 7/12; B32B 27/285; B32B 27/34; B32B 27/36; H10K 59/871; H10K 77/111; H10K 2102/311

(57) ABSTRACT

In a laminated film according to an embodiment, an elastic layer containing polyether-block-amide and a hard coating-treated base film are laminated. Due to the layer configuration in which different materials are compounded, the surface hardness and restoration properties and elasticity can be improved at the same time, and also, excellent optical properties can be implemented.

### TECHNICAL FIELD

Embodiments relate to a laminate film with enhanced surface hardness and restorability and to a display device comprising the same.

### BACKGROUND ART

Display technologies continue to develop driven by the demand in tandem with the development in IT devices. Technologies on curved displays and bent displays have already been commercialized. In recent years, flexible display devices that can be flexibly bent or folded in response to an external force are preferred in the field of mobile devices that require large screens and portability at the same time. In particular, a foldable display device has the great advantages that it is folded to a smaller size to enhance its portability when not in use, and it is unfolded to form a larger screen when in use.

The cover window in such a flexible display device is required to be flexible and have restorability. In addition, in an out-folding type, in which the display is exposed to the outside, it is required to have not only flexible characteristics but also protection against external forces.

A display device mainly adopts a polymer film such as transparent polyimide or polyester or glass substrate for its cover window. But a polymer film is vulnerable to external scratches, and a glass substrate has a problem of lack of flexibility.

In order to solve this problem, Korean Laid-open Patent Publication No. 2019-0026611 discloses a hard coating film manufactured by sequentially forming a high bending layer and a high hardness layer using a siloxane resin on a transparent substrate to enhance scratch resistance and flexibility.

### PRIOR ART DOCUMENT

(Patent Document 1) Korean Laid-open Patent Publication No. 2019-0026611

### DISCLOSURE OF INVENTION

### Technical Problem

Films for cover windows of displays developed so far have had limitations in implementing both surface hardness and restorability or elasticity. In addition, when a hard coating layer is formed to enhance surface hardness, there is a problem in that flexibility or restorability is significantly deteriorated, or the optical properties of the film is deteriorated.

As a result of research conducted by the present inventors, it has been discovered that as an elastic layer comprising a polyether-block-amide is laminated with a base film treated with a hard coating, not only can both surface hardness and restorability or elasticity be enhanced, but excellent optical properties can also be achieved.

Accordingly, the embodiments to be described below aim to provide a laminate film with enhanced surface hardness and restorability or elasticity, along with excellent optical properties, and a display device comprising the same.

### Solution to Problem

According to an embodiment, there is provided a laminate film, which comprises a base film; a hard coating layer disposed on one side of the base film; and an elastic layer disposed on the other side of the base film, wherein the elastic layer comprises a polyether-block-amide.

According to another embodiment, there is provided a display device, which comprises a display panel; and a cover window disposed on the front side of the display panel, wherein the cover window comprises a base film; a hard coating layer disposed on one side of the base film; and an elastic layer disposed on the other side of the base film, and the elastic layer comprises a polyether-block-amide.

### Advantageous Effects of Invention

In the laminate film according to an embodiment, an elastic layer comprising a polyether-block-amide is laminated with a base film treated with a hard coating; thus, not only can both surface hardness and restorability or elasticity be enhanced by virtue of the layer configuration where different materials are combined, but excellent optical properties can also be achieved.

Accordingly, when the laminate film according to the embodiment is applied to the cover of a flexible display device, for example, a cover window of an out-folding type device in which the display is exposed to the outside or an in-folding type device, it can have the protection performance of the display against external forces, along with flexible characteristics, and its optical properties can be excellent.

### BRIEF DESCRIPTION OF DRAWINGS

FIG. 1 shows an exploded perspective view of a display device according to an embodiment.

FIG. 2 shows a cross-sectional view of a laminate film according to an embodiment (A-A′ in FIG. 1).

FIG. 3 shows before (a) and after (b) the indentation in a nanoindentation test.

FIG. 4 shows a cross-sectional view of a sample at the time of indentation (a) and release (b) by an indenter tip.

FIGS. 5a and 5b each show in-folding and out-folding type flexible display devices.

### DESCRIPTION OF THE NUMERALS

1: display device
1a: in-folding type flexible display device
1b: out-folding type flexible display device
2: indenter, 2a: indenter tip, 2b: mark (dent) left after release of indentation,
10: laminate film (cover window), 10a: sample, 20: display panel
30: board, 40: frame, 100: base film, 200: hard coating layer, 300: elastic layer
Aₚ: contact projection area, F: test force, Fₘₐₓ: maximum test force,
hₘₐₓ: maximum indentation depth at maximum test force
hₚ: indentation depth after release of test force

### BEST MODE FOR CARRYING OUT THE INVENTION

Hereinafter, various embodiments and examples will be described in detail by referring to the drawings.

In the description of the following embodiments, if it is determined that a detailed description of a relevant known constitution or function may obscure the subject matter, the detailed description thereof will be omitted. In addition, the sizes of individual elements in the drawings may be exaggeratedly depicted or omitted for the sake of description, and they may differ from the actual sizes.

In the present specification, when one component is described to be formed on/under another component or connected or coupled to each other, it covers the cases where these components are directly or indirectly formed, connected, or coupled through another component. In addition, it should be understood that the reference for the on/under position of each component may vary depending on the direction in which the object is observed.

In this specification, terms referring to the respective components are used to distinguish them from each other and are not intended to limit the scope of the embodiment. In addition, in the present specification, a singular expression is interpreted to cover a plural number as well unless otherwise specified in the context.

In the present specification, the term “comprising” is intended to specify a particular characteristic, region, step, process, element, and/or component. It does not exclude the presence or addition of any other characteristic, region, step, process, element and/or component, unless specifically stated to the contrary.

In the present specification, the terms first, second, and the like are used to describe various components. But the components should not be limited by the terms. The terms are used for the purpose of distinguishing one element from another.

The molecular weight of a compound or polymer described in the present specification, for example, a number average molecular weight or a weight average molecular weight, is a relative mass based on carbon-12 as is well known. Although its unit is not described, it may be understood as a molar mass (g/mole) of the same numerical value, if necessary.

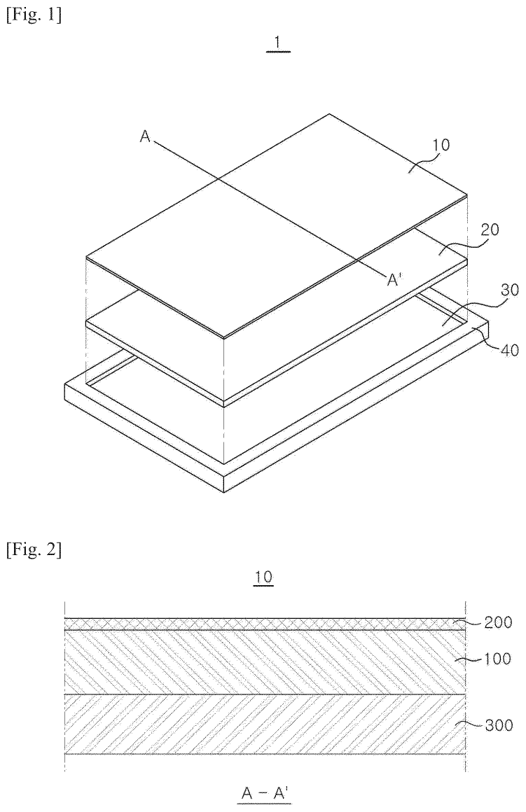

FIG. 1 shows an exploded perspective view of a display device according to an embodiment. FIG. 2 shows a cross-sectional view of a laminate film (cover window) according to an embodiment (A-A′ in FIG. 1).

Referring to FIG. 2, the laminate film (10) according to an embodiment comprises a base film (100); a hard coating layer (200) disposed on one side of the base film (100); and an elastic layer (300) disposed on the other side of the base film, wherein the elastic layer (300) comprises a polyether-block-amide.

In the laminate film according to an embodiment, an elastic layer comprising a polyether-block-amide is laminated with a base film treated with a hard coating; thus, not only can both surface hardness and restorability or elasticity be enhanced by virtue of the layer configuration where different materials are combined, but excellent optical properties can also be achieved.

### Surface Hardness of the Laminate Film

The surface hardness of the laminate film may be measured by a nanoindentation test.

Nanoindentation is an analysis technique in which an indenter having a certain geometric shape is forced to the surface of a material with a small force (load) at a μN to mN level and then released to obtain a force-displacement curve, which is analyzed to measure various mechanical properties such as tensile properties and residual stress as well as hardness and elastic modulus.

The indenter tip may have a variety of geometric shapes. For example, it may have a conical, a pyramidal or triangular pyramid (Berkovich triangular or Vickers triangular), or a cylindrical flat punch shape.

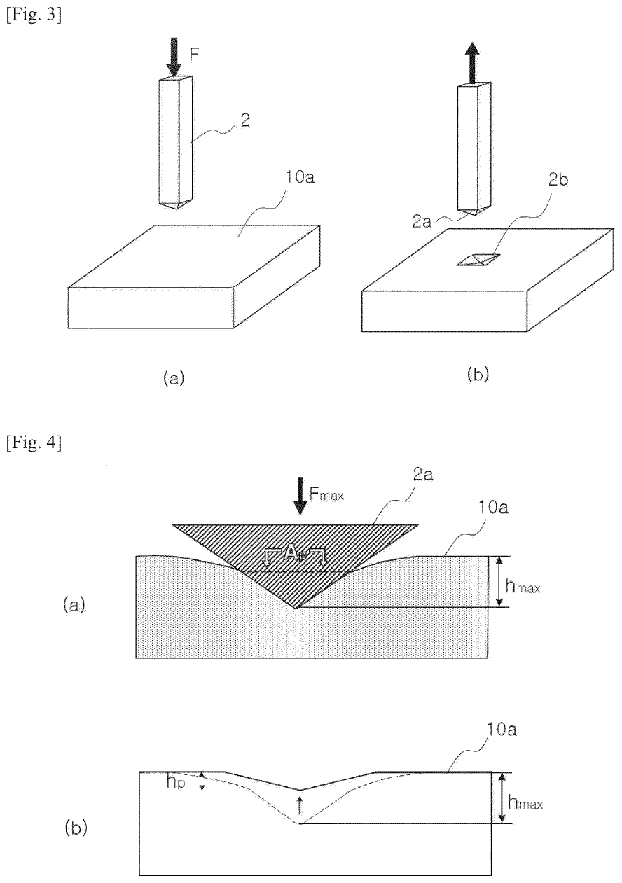

FIG. 3 shows before (a) and after (b) the indentation of a sample in a nanoindentation test.

FIG. 4 shows a cross-sectional view of a sample at the time of indentation (a) and release (b) by an indenter tip.

Referring to FIGS. 3 and 4, since common polymer materials are viscoelastic, when a sample (10a) is indented by the tip (2a) in the lower end of an indenter (2), it is deformed to the maximum depth (hₘₐₓ) at the maximum test force. Thereafter, when the indenter (2) is removed to release the indentation by the indenter tip (2a), the deformation is in part restored due to the elasticity of the polymer, whereas the rest is not permanently restored, thereby leaving a dent (2b) having a certain depth (hₚ).

In this nanoindentation test, the stiffness(S), projected contact area (Aₚ), test force (F), maximum indentation depth (hₘₐₓ) at maximum force, and the like are measured, and a force-displacement curve is obtained. Based on these results, the indentation modulus (E_{IT}), indentation hardness (H_{IT}), Vickers hardness (H_{V}), Martens hardness (H_{M}), indentation creep (C_{IT}), recovery relation (η_{IT}), and the like may be calculated. The nanoindentation test may be carried out according to, for example, the ISO 14577-1:2002(E) standard.

Martens hardness (HM), also called composite hardness, is calculated from the indentation depth at which the test force is applied. Unlike indentation hardness, it provides plastic and elastic material properties. The laminate film according to an embodiment may have a Martens hardness of, for example, 250 N/mm² or more, 260 N/mm² or more, 270 N/mm² or more, or 275 N/mm² or more, and 400 N/mm² or less, 350 N/mm² or less, 330 N/mm² or less, 310 N/mm² or less, or 290 N/mm² or less. As a specific example, the laminate film may have a Martens hardness (HM) of 250 N/mm² or more, more specifically, 250 N/mm² to 350 N/mm², when measured for the surface of the hard coating layer by a nanoindentation test according to the ISO 14577-1:2002(E) standard.

Vickers hardness (HV) is calculated by multiplying indentation hardness (H_{IT}) by 0.0945 (H_{IT}×0.0945) and may be measured according to, for example, the ISO 14577-1:2002(E) standard. Plastic properties such as ductility, malleability, and impact resistance may be obtained from the Vickers hardness (HV). The laminate film according to an embodiment may have a Vickers hardness (HV) of, for example, 40 N/mm² or more, 45 N/mm² or more, 48 N/mm² or more, or 49 N/mm² or more, and 60 N/mm² or less, 55 N/mm² or less, or 53 N/mm² or less. As a specific example, the laminate film may have a Vickers hardness (HV) of 48 N/mm² or more, more specifically, 48 N/mm² to 55 N/mm², when measured for the surface of the hard coating layer by a nanoindentation test according to the ISO 14577-1:2002(E) standard.

The high Vickers hardness (HV) of the laminate film according to an embodiment may be attributable to the hard coating layer. For example, the laminate film may have an HV increase (N/mm²), as calculated by the following equation, of 1.5 N/mm² or more, specifically, 2.0 N/mm² or more or 2.5 N/mm² or more, as a more specific example, 1.5 N/mm² to 7.0 N/mm².

$$HV increase ( N / {mm}^{2} ) = HV 1 ( N / {mm}^{2} ) - HV 2 ( N / {mm}^{2} )$$

Here, HV1 is the Vickers hardness (HV) (N/mm²) of the laminate film, and HV2 is the Vickers hardness (HV) (N/mm²) of a film having a layer structure excluding the hard coating layer from the laminate film.

Indentation hardness (H_{IT}) is also called plastic hardness, which is a measure of the resistance of a material to permanent (plastic) deformation at maximum force. Plastic properties such as ductility, malleability, and impact resistance can be obtained therefrom. Specifically, the indentation hardness (H_{IT}) is calculated as a value (Fₘₐₓ/Aₚ) of the maximum test force (Fₘₐₓ) divided by the projected contact area (Aₚ) at the penetration depth. The laminate film according to an embodiment may have an indentation hardness (H_{IT}) of, for example, 500 N/mm² or more, 505 N/mm² or more, 510 N/mm² or more, 515 N/mm² or more, 520 N/mm² or more, or 524 N/mm² or more, and 550 N/mm² or less, 545 N/mm² or less, 540 N/mm² or less, or 535 N/mm² or less. As a specific example, the laminate film may have an indentation hardness (H_{IT}) of 505 N/mm² or more, more specifically, 505 N/mm² to 550 N/mm², when measured for the surface of the hard coating layer by a nanoindentation test according to the ISO 14577-1:2002(E) standard. Within the above indentation hardness (H_{IT}) range, plastic properties such as impact resistance are exerted, making it advantageous for the application as the cover window of a display device.

The high indentation hardness (H_{IT}) of the laminate film according to an embodiment may be attributable to the hard coating layer. For example, the laminate film may have an H_{IT} increase (N/mm²), as calculated by the following equation, of 10 N/mm² or more, specifically, 15 N/mm² or more, 20 N/mm² or more, or 25 N/mm², as a more specific example, 10 N/mm² to 70 N/mm².

$${H}_{IT} increase ( N / {mm}^{2} ) = {H}_{IT} 1 ( N / {mm}^{2} ) - {H}_{IT} 2 ( N / {mm}^{2} )$$

Here, H_{IT}1 is the indentation hardness (H_{IT}) (N/mm²) of the laminate film, and H_{IT}2 is the indentation hardness (H_{IT}) (N/mm²) of a film having a layer structure excluding the hard coating layer from the laminate film.

Indentation modulus (E_{IT}) may be calculated using the Poisson's ratio of a sample and an indenter, the modulus of the indenter, and the reduced modulus of the indentation contact, which may be measured by a nanoindentation test according to, for example, the ISO 14577-1:2002(E) standard. Elastic properties such as degree of hardness and abrasion resistance may be obtained from the indentation modulus (Err). The indentation modulus (Err) of the laminate film according to an embodiment may be, for example, 3,600 MPa or more, 3,800 MPa or more, 4,000 MPa or more, or 4,200 MPa or more, and 5,000 MPa or less, 4,800 MPa or less, 4,600 MPa or less, or 4,500 MPa or less. As a specific example, the laminate film may have an indentation modulus (E_{IT}) of 3,800 MPa or more, more specifically, 3,800 MPa to 4,800 MPa, when measured for the surface of the hard coating layer by a nanoindentation test according to the ISO 14577-1:2002(E) standard.

Indentation creep (C_{IT}) describes further deformation of a material at a constant force. In order to measure indentation creep (C_{IT}), an indenter is pressed onto a sample at a constant force over a longer period of time (minutes to hours). It may be calculated by measuring the indentation depth increased by the continued pressing. The indentation creep (C_{IT}) of the laminate film according to an embodiment may be, for example, 3.0% or more, 3.3% or more, 3.5% or more, 3.6% or more, or 3.7% or more, and 4.5% or less, 4.3% or less, 4.1% or less, 4.0% or less, or 3.9% or less. As a specific example, the laminate film may have an indentation creep (C_{IT}) of 3.3% or more, more specifically, 3.3% to 4.2%, when measured for the surface of the hard coating layer by a nanoindentation test according to the ISO 14577-1:2002(E) standard.

Recovery relation (η_{IT}) may be calculated as a percentage (i.e., (Wₑₗₐₛₜ/Wₜₒₜₐₗ)×100, %) of the elastic reserve deformation work (Wₑₗₐₛₜ) to the total mechanical work of indentation (Wₜₒₜₐₗ) in a force-depth curve obtained by the indentation of an indenter onto a sample surface and then release thereof, which may be measured according to, for example, the ISO 14577-1:2002(E) standard. The recovery relation (η_{IT}) of the laminate film according to an embodiment may be, for example, 60% or more, 65% or more, 68% or more, or 70% or more, and 85% or less, 80% or less, 78% or less, or 75% or less. As a specific example, the laminate film may have a recovery relation (η_{IT}) of 68% or more, more specifically, 68% to 78%, when measured for the surface of the hard coating layer by a nanoindentation test according to the ISO 14577-1:2002(E) standard.

Recovery may be calculated by the following equation based on the values measured by a nanoindentation test. The recovery of the laminate film according to an embodiment may be, for example, 65% or more, 70% or more, 75% or more, 76% or more, or 78% or more, and 95% or less, 90% or less, 85% or less, or 83% or less. As a specific example, the laminate film may have a recovery of 76% or more, more specifically, 76% to 90%, when measured for the surface of the hard coating layer by a nanoindentation test according to the ISO 14577-1:2002(E) standard. The recovery may be calculated by the following equation.

$$Recovery ( \% ) = [ ( {h}_{m ax ( at 30 mN )} - {h}_{p} ) / {h}_{m ax ( at 30 mN )} ] \times 100$$

Here, hₘₐₓ (at 30 mN) is the maximum indentation depth (μm) during which the surface of the hard coating layer is pressed downward for 15 seconds at a force of 30 mN and held (crept) for 5 seconds, and hₚ is the depth (μm) of the indentation that remains unrecovered even after the force is released.

The high recovery of the laminate film according to an embodiment may be attributable to the hard coating layer or the elastic layer. For example, the laminate film may have a recovery increase (%), as calculated by the following equation, of 2% or more, specifically, 3% or more or 5% or more, as a more specific example, 3% to 20%.

$$Recovery increase ( \% ) = Recovery 1 ( \% ) - Recovery 2 ( \% )$$

Here, Recovery1 is the recovery (%) of the laminate film, and Recovery2 is the recovery (%) of a film having a layer structure excluding any one of the hard coating layer and the elastic layer from the laminate film.

### Optical Properties of the Laminate Film

The laminate film may have a light transmittance, for example, an average visible light transmittance of at least a certain level. As a result, it is advantageous to be applied to a cover window of a display device. For example, the laminate film may have an average visible light transmittance of 70% or more, 75% or more, 80% or more, 82% or more, 83% or more, or 85% or more. Meanwhile, the upper limit of the average visible light transmittance range of the laminate film is not particularly limited. It may be, for example, 100% or less, 95% or less, or 90% or less. The transmittance may be measured, for example, according to the ISO 13468 standard. As a specific example, the laminate film may have an average visible light transmittance of 80% or more or 85% or more when measured according to the ISO 13468 standard.

In addition, the laminated film may have an effect of an increase in transmittance due to the hard coating. For example, the laminate film may have a transmittance increase (%), as calculated by the following equation, of 2% or more, specifically, 2.5% or more, 3% or more, 4% or more, or 5% or more, as a more specific example, 2% to 10% or 3% to 10%.

$$Transmittance increase ( \% ) = TT 1 ( \% ) - TT 2 ( \% )$$

Here, TT1 is the average visible light transmittance (%) of the laminate film, and TT2 is the average visible light transmittance (%) of a film having a layer structure excluding the hard coating layer from the laminate film. The average visible light transmittance is measured under the same conditions according to the ISO 13468 standard.

According to an embodiment, the laminate film may have an average visible light transmittance of 85% or more when measured according to the ISO 13468 standard and a transmittance increase of 3% or more as calculated by the above equation.

In addition, the laminate film may have a haze of a certain level or less. As a result, it is advantageous to be applied to a cover window of a display device. For example, the laminate film may have a haze of 5% or less, 4% or less, 3.5% or less, 3% or less, or 2% or less. Meanwhile, the lower limit of the haze range of the laminate film is not particularly limited. It may be, for example, 0% or more, 0.5% or more, or 1% or more. The haze may be measured, for example, according to the ISO 14782 standard. As a specific example, the laminate film may have a haze of 4% or less when measured according to the ISO 14782 standard.

According to an embodiment, the laminate film may have an average visible light transmittance of 80% or more when measured according to the ISO 13468 standard, a haze of 4% or less when measured according to the ISO 14782 standard, and a transmittance increase of 2% or more as calculated by the above equation.

In addition, the laminate film may have a yellow index of a certain level or less. As a result, images appearing on the display can be recognized without distortion. For example, the laminate film may have a yellow index of 2 or less, 1.5 or less, or 1 or less. Meanwhile, the lower limit of the yellow index range of the laminate film is not particularly limited. It may be, for example, 0 or more, 0.3 or more, 0.5 or more, or 0.6 or more. The yellow index (YI) may be measured using a spectrophotometer according to the ASTM-E313 standard, and D65 may be for example used as a light source. As a specific example, the laminate film may have a yellow index of 1.5 or less when measured at 10° using a D65 light source according to the ASTM-E313 standard.

In addition, the laminated film may have the effect of a decrease in yellow index due to the hard coating. For example, the laminate film may have a yellow index decrease, as calculated by the following equation, of 0.5 or more, specifically, 0.7 or more or 1.0 or more, as a more specific example, 0.5 to 5.

$$Yellow index decrease ( \% ) = YI 2 - YI 1$$

Here, YI1 is the yellow index of the laminate film, and YI2 is the yellow index of a film having a layer structure excluding the hard coating layer from the laminate film. The yellow index is measured under the same conditions at 10° using a D65 light source according to the ASTM-E313 standard.

In addition, the color of the laminated film can be adjusted to a specific range. As a result, images appearing on the display can be recognized without distortion. For example, the L* value of transparent color in the CIE Lab color coordinates of the laminated film may be 85 or more, 90 or more, or 93 or more, and may be 100 or less, 97 or less, or 95 or less. In addition, the a* value of transparent color in the CIE Lab color coordinates of the laminated film may be −3 or more, −2 or more, −1.5 or more, or −1 or more, and 2 or less, 1 or less, 0 or less, −0.5 or less, or −0.9 or less. For example, the b* value of transparent color in the CIE Lab color coordinates of the laminated film may be −2 or more, −1 or more, 0 or more, or 0.5 or more, and 3 or less, 2 or less, 1.5 or less, or 1 or less. The transparent color may be measured using a spectrophotometer, and D65 may be for example used as a light source. As a specific example, the laminate film may have an L* value of 92 or more, an a* value of −2 to 1, and a b* value of −1 to 2 of transparent color in the CIE Lab color coordinates when measured using a D65 light source.

### Base Film (100)

The base film (100) serves as a base layer of the primer layer (200) while imparting mechanical properties to the laminate film (10).

The base film may be a polymer film or a glass substrate, specifically, a reinforced glass substrate with a thickness of less than about 100 μm. For example, the base film may comprise a polymer film or ultra-thin glass (UTG).

Specifically, the base film may be a polymer film. That is, the base film may comprise a polymer resin.

Examples of a polymer resin contained in the base film include polyester resins such as polyethylene terephthalate, polyethylene isophthalate, polyethylene naphthalate, and polybutylene terephthalate; cellulose-based resins such as diacetylcellulose and triacetylcellulose; polycarbonate-based resins; acrylic resins such as polymethyl (meth)acrylate and polyethyl (meth)acrylate; styrene-based resins such as polystyrene and acrylonitrile-styrene copolymers; polyolefin resins such as polyethylene, polypropylene, polyolefins with cyclo- or norbornene structures, and ethylene-propylene copolymers; vinyl chloride-based resin; amide resins such as nylon and aromatic polyamide; imide-based resins; polyamide-imide-based resins; polyethersulfone resins; polyurethane resins; sulfone-based resins; polyetheretherketone-based resins; sulfated polyphenylene resins; vinyl alcohol-based resins; vinylidene chloride-based resins; vinyl butyral-based resins; allylate-based resins; polyoxymethylene-based resins; and epoxy-based resins. They may be used alone or in combination of two or more.

The base film may further comprise a filler in addition to the polymer resin. As an example, the base film may comprise a polyimide-based resin and a filler.

The filler may be at least one selected from the group consisting of barium sulfate, silica, and calcium carbonate. As the base film comprises the filler, it is possible to enhance the roughness and windability and to enhance the sliding performance and the effect of improving scratches in the preparation of the film.

The filler may have a particle diameter of 0.01 μm to less than 1.0 μm. For example, the particle diameter of the filler may be 0.05 μm to 0.9 μm or 0.1 μm to 0.8 μm, but it is not limited thereto.

The filler may be employed in an amount of 0.01% by weight to 3% by weight based on the total weight of the base film. For example, the filler may be employed in an amount of 0.05% by weight to 2.5% by weight, 0.1% by weight to 2% by weight, or 0.2% by weight to 1.7% by weight, based on the total weight of the base film, but it is not limited thereto.

The base film may have a thickness of 20 μm or more, 30 μm or more, 40 μm or more, 50 μm or more, or 100 μm or more, and 500 μm or less, 400 μm or less, 300 μm or less, or 200 μm or less. As a specific example, the thickness of the base film may be 20 μm to 500 μm, more specifically 40 μm to 200 μm or 50 μm to 200 μm.

The base film may have optical properties and mechanical properties adjusted to certain ranges.

The base film may have a haze of 3% or less. For example, the haze of the base film may be 2% or less, 1.5% or less, or 1% or less, but it is not limited thereto.

The base film may have a yellow index (YI) of 5 or less. For example, the yellow index of the base film may be 4 or less, 3.8 or less, 2.8 or less, 2.5 or less, 2.3 or less, or 2.1 or less, but it is not limited thereto.

The base film may have a modulus of 5 GPa or more. For example, the modulus of the base film may be 5.2 GPa or more, 5.5 GPa or more, 6.0 GPa or more, 10 GPa or less, 5 GPa to 10 GPa, or 7 GPa to 10 GPa, but it is not limited thereto.

The base film may have a light transmittance of 80% or more. For example, the light transmittance of the base film may be 85% or more, 88% or more, 89% or more, 80% to 99%, or 85% to 99%, but it is not limited thereto.

The base film may have a compressive strength of 0.4 kgf/μm or more. Specifically, the compressive strength of the base film may be 0.45 kgf/μm or more, or 0.46 kgf/μm or more, but it is not limited thereto.

The base film may have a surface hardness of HB or higher. Specifically, the surface hardness of the base film may be H or higher, or 2H or higher, but it is not limited thereto.

The base film may have a tensile strength of 15 kgf/mm² or more. Specifically, the tensile strength of the base film may be 18 kgf/mm² or more, 20 kgf/mm² or more, 21 kgf/mm² or more, or 22 kgf/mm² or more, but it is not limited thereto.

The base film may have an elongation of 15% or more. Specifically, the elongation of the base film may be 16% or more, 17% or more, or 17.5% or more, but it is not limited thereto.

### Polyimide-Based Resin

As an example, the base film may comprise a polyimide-based resin. Specifically, the base film may be a transparent polyimide-based film. The polyimide-based resin may be prepared by simultaneously or sequentially reacting reactants that comprise a diamine compound and a dianhydride compound. Specifically, the polyimide-based resin may comprise a polyimide-based polymer prepared by polymerizing a diamine compound and a dianhydride compound. The polyimide-based resin may comprise an imide repeat unit derived from the polymerization of a diamine compound and a dianhydride compound. In addition, the polyimide-based resin may be polymerized by further comprising a dicarbonyl compound. As a result, it may comprise a polyamide-imide-based polymer that further comprises an amide repeat unit derived from the polymerization of a diamine compound and a dicarbonyl compound.

The diamine compound is not particularly limited, but it may be, for example, an aromatic diamine compound that contains an aromatic structure. For example, the diamine compound may be a compound represented by the following Formula 1.

H₂N-(E)ₑ-NH₂ [Formula 1]

In Formula 1, E is selected from a substituted or unsubstituted divalent C₆-C₃₀ aliphatic cyclic group, a substituted or unsubstituted divalent C₄-C₃₀ heteroaliphatic cyclic group, a substituted or unsubstituted divalent C₆-C₃₀ aromatic cyclic group, a substituted or unsubstituted divalent C₄-C₃₀ heteroaromatic cyclic group, a substituted or unsubstituted C₁-C₃₀ alkylene group, a substituted or unsubstituted C₂-C₃₀ alkenylene group, a substituted or unsubstituted C₂-C₃₀ alkynylene group, —C(═O)—, —CH(OH)—, —S(═O)₂—, —Si(CH₃)₂—, —C(CH₃)₂—, and —C(CF₃)₂—. e is selected from integers of 1 to 5. When e is 2 or more, the Es may be the same as, or different from, each other.

In the present specification, the term “substituted” means to be substituted with at least one substituent group selected from the group consisting of deuterium, —F, —Cl, —Br, —I, a hydroxyl group, a cyano group, a nitro group, an amino group, an amido group, a hydrazine group, a hydrazone group, an ester group, a ketone group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₆-C₃₀ alicyclic organic group, a substituted or unsubstituted C₄-C₃₀ heterocyclic group, a substituted or unsubstituted C₆-C₃₀ aryl group, and a substituted or unsubstituted C₄-C₃₀ heteroaryl group. Two substituents adjacent to each other may be linked to form a ring.

(E)ₑ in Formula 1 may be selected from the groups represented by the following Formulae 1-1a to 1-14a, but it is not limited thereto.

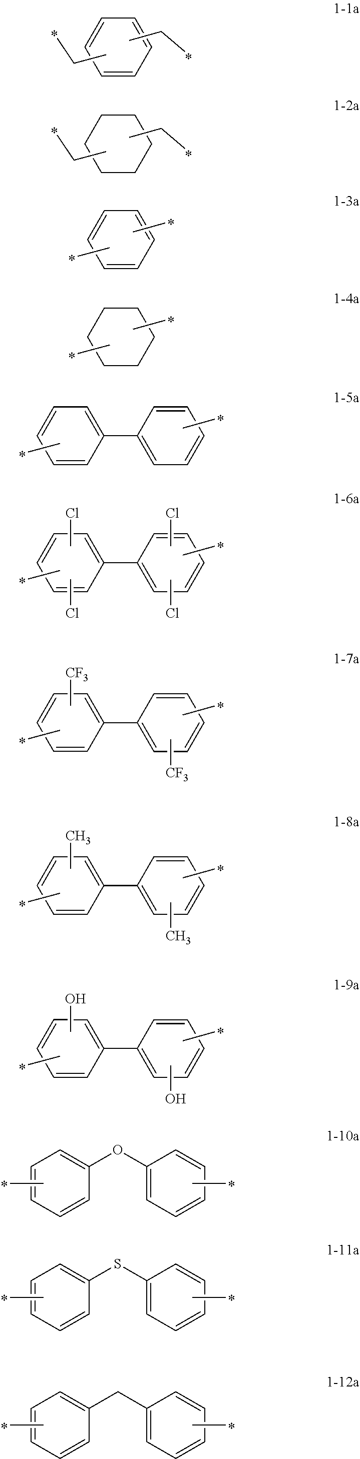

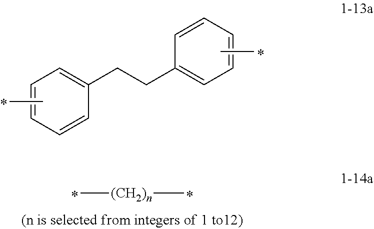

Specifically, (E)ₑ in Formula 1 may be selected from the groups represented by the following Formulae 1-1b to 1-13b, but it is not limited thereto.

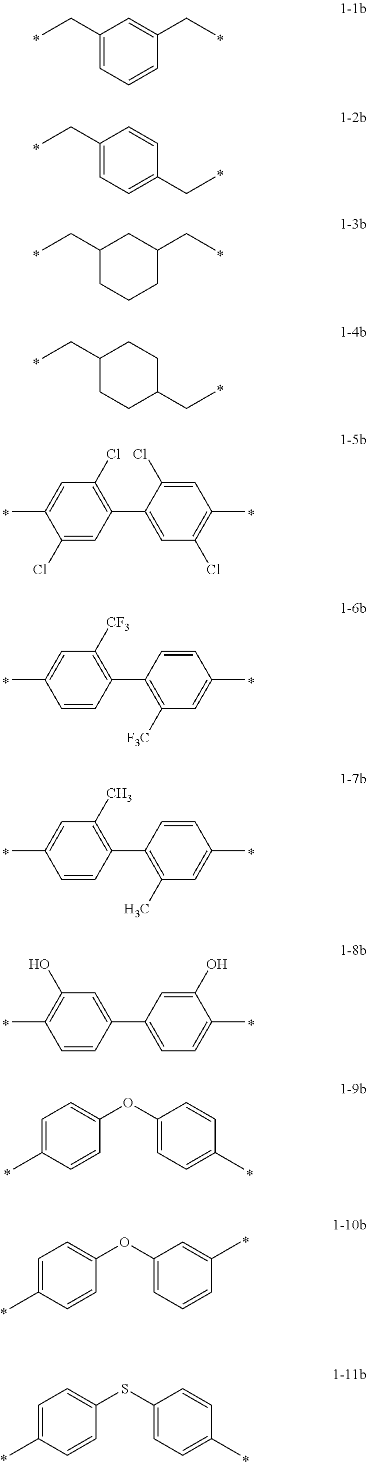

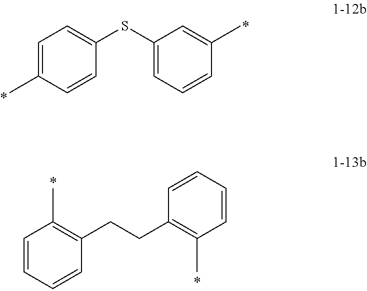

More specifically, (E)ₑ in the above Formula 1 may be the group represented by the above Formula 1-6b.

In an embodiment, the diamine compound may comprise a compound having a fluorine-containing substituent. Alternatively, the diamine compound may be composed of a compound having a fluorine-containing substituent. In such an event, the fluorine-containing substituent may be a fluorinated hydrocarbon group and specifically may be a trifluoromethyl group. But it is not limited thereto.

In an embodiment, one kind of diamine compound may be used as the diamine compound. That is, the diamine compound may be composed of a single component.

For example, the diamine compound may comprise 2,2′-bis(trifluoromethyl)-4,4′-diaminobiphenyl (TFDB) represented by the following formula, but it is not limited thereto.

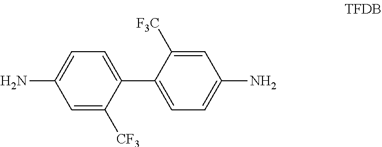 [SMILES: Nc1ccc(-c2ccc(N)cc2C(F)(F)F)c(C(F)(F)F)c1]

The dianhydride compound has a low birefringence value, so that it can contribute to enhancements in the optical properties such as transmittance of a film that comprises the polyimide-based resin.

The dianhydride compound is not particularly limited, but it may be an aromatic dianhydride compound that contains an aromatic structure. For example, the aromatic dianhydride compound may be a compound represented by the following Formula 2.

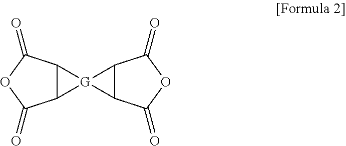

In Formula 2, G may be a group selected from a substituted or unsubstituted tetravalent C₆-C₃₀ aliphatic cyclic group, a substituted or unsubstituted tetravalent C₄-C₃₀ heteroaliphatic cyclic group, a substituted or unsubstituted tetravalent C₆-C₃₀ aromatic cyclic group, or a substituted or unsubstituted tetravalent C₄-C₃₀ heteroaromatic cyclic group, wherein the aliphatic cyclic group, the heteroaliphatic cyclic group, the aromatic cyclic group, or the heteroaromatic cyclic group may be present alone, may be fused to each other to form a condensed ring, or may be bonded by a bonding group selected from a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, —C(CH₃)₂—, and —C(CF₃)₂—.

G in the above Formula 2 may be selected from the groups represented by the following Formulae 2-1a to 2-9a, but it is not limited thereto.

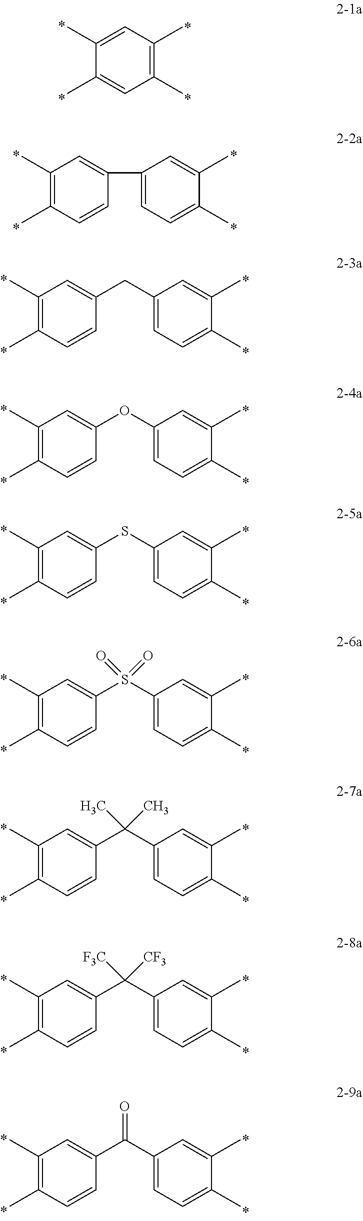

For example, G in the above Formula 2 may be the group represented by the above Formula 2-8a.

In an embodiment, the dianhydride compound may comprise a compound having a fluorine-containing substituent. Alternatively, the dianhydride compound may be composed of a compound having a fluorine-containing substituent. In such an event, the fluorine-containing substituent may be a fluorinated hydrocarbon group and specifically may be a trifluoromethyl group. But it is not limited thereto.

In another embodiment, the dianhydride compound may be composed of a single component or a mixture of two components.

For example, the dianhydride compound may comprise 2,2′-bis-(3,4-dicarboxyphenyl)hexafluoropropane dianhydride (6-FDA) represented by the following formula, but it is not limited thereto.

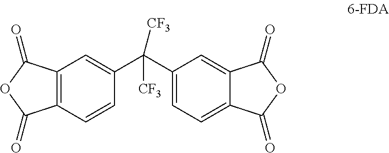 [SMILES: O=C1OC(=O)c2cc(C(c3ccc4c(c3)C(=O)OC4=O)(C(F)(F)F)C(F)(F)F)ccc21]

The diamine compound and the dianhydride compound may be polymerized to form a polyamic acid.

Subsequently, the polyamic acid may be converted to a polyimide through a dehydration reaction.

The polyimide may comprise a repeat unit represented by the following Formula A.

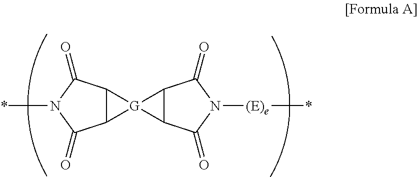

In Formula A, E, G, and e are as described above.

For example, the polyimide may comprise a repeat unit represented by the following Formula A-1, but it is not limited thereto.

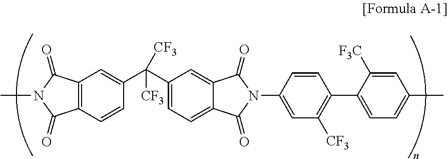

In Formula A-1, n may be an integer of 1 to 400.

The dicarbonyl compound is not particularly limited, but it may be, for example, a compound represented by the following Formula 3.

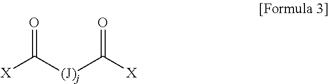

In Formula 3, J is selected from a substituted or unsubstituted divalent C₆-C₃₀ aliphatic cyclic group, a substituted or unsubstituted divalent C₄-C₃₀ heteroaliphatic cyclic group, a substituted or unsubstituted divalent C₆-C₃₀ aromatic cyclic group, a substituted or unsubstituted divalent C₄-C₃₀ heteroaromatic cyclic group, a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, —C(CH₃)₂—, and —C(CF₃)₂—. j is selected from integers of 1 to 5. When j is 2 or more, the Js may be the same as, or different from, each other. X is a halogen atom. Specifically, X may be F, Cl, Br, I, or the like. More specifically, X may be Cl, but it is not limited thereto.

(J)ⱼ in the above Formula 3 may be selected from the groups represented by the following Formulae 3-1a to 3-14a, but it is not limited thereto.

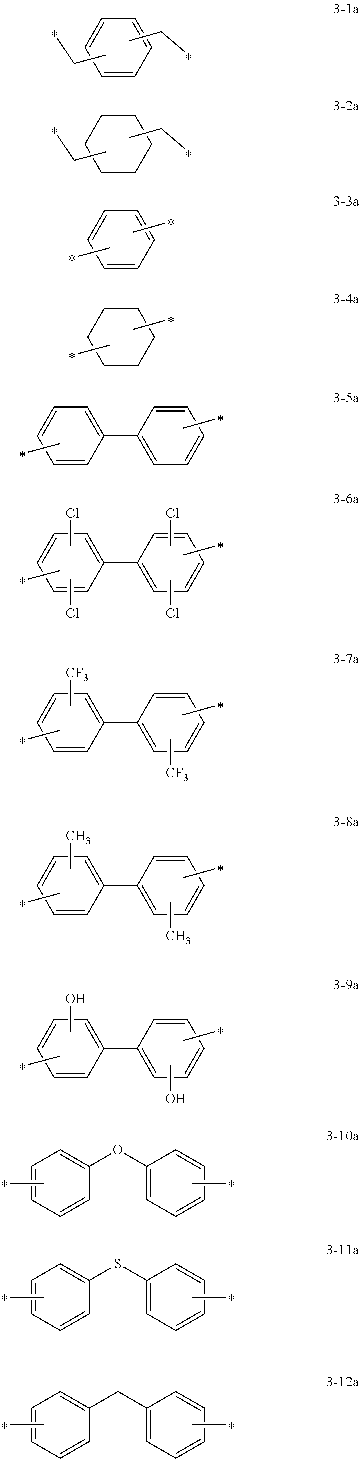

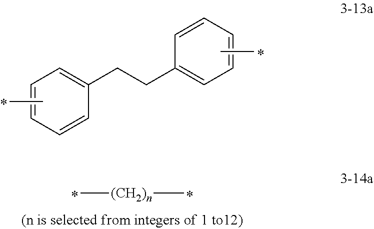

Specifically, (J)ⱼ in the above Formula 3 may be selected from the groups represented by the following Formulae 3-1b to 3-8b, but it is not limited thereto.

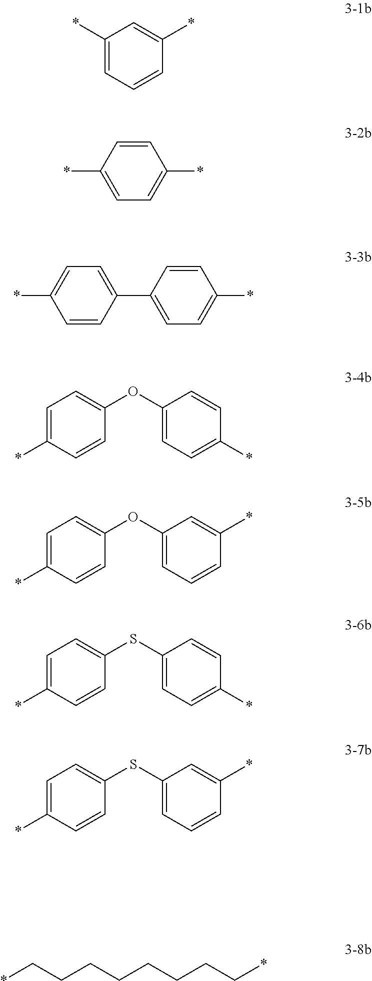

More specifically, (J)ⱼ in Formula 3 may be the group represented by the above Formula 3-1b, the group represented by the above Formula 3-2b, or the group represented by the above Formula 3-3b.

In an embodiment, a mixture of at least two kinds of dicarbonyl compounds different from each other may be used as the dicarbonyl compound. If two or more dicarbonyl compounds are used, at least two dicarbonyl compounds in which (J)ⱼ in the above Formula 3 is selected from the groups represented by the above Formulae 3-1b to 3-8b may be used as the dicarbonyl compound.

In another embodiment, the dicarbonyl compound may be an aromatic dicarbonyl compound that contains an aromatic structure.

For example, the dicarbonyl compound may comprise a first dicarbonyl compound and/or a second dicarbonyl compound different from the first dicarbonyl compound.

The first dicarbonyl compound and the second dicarbonyl compound may be an aromatic dicarbonyl compound, respectively.

The first dicarbonyl compound and the second dicarbonyl compound may be aromatic dicarbonyl compounds different from each other, but they are not limited thereto.

If the first dicarbonyl compound and the second dicarbonyl compound are an aromatic dicarbonyl compound, respectively, they comprise a benzene ring. Thus, they can contribute to improvements in the mechanical properties such as surface hardness and tensile strength of a film thus produced that comprises the polyamide-imide resin.

The dicarbonyl compound may comprise terephthaloyl chloride (TPC), isophthaloyl chloride (IPC), and 1,1′-biphenyl-4,4′-dicarbonyl dichloride (BPDC), as represented by the following formulae, or a combination thereof. But it is not limited thereto.

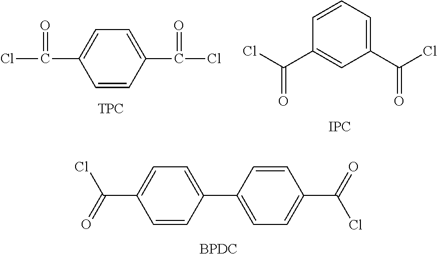

For example, the first dicarbonyl compound may comprise BPDC, and the second dicarbonyl compound may comprise TPC, but they are not limited thereto.

Specifically, if BPDC is used as the first dicarbonyl compound and TPC is used as the second dicarbonyl compound in a proper combination, a film that comprises the polyamide-imide-based resin thus produced may have high oxidation resistance.

Alternatively, the first dicarbonyl compound may comprise IPC (isophthaloyl chloride), and the second dicarbonyl compound may comprise TPC, but they are not limited thereto.

Specifically, if IPC is used as the first dicarbonyl compound and TPC is used as the second dicarbonyl compound in a proper combination, a film that comprises the polyamide-imide-based resin thus produced may have high oxidation resistance, along with reduced manufacturing costs.

The diamine compound and the dicarbonyl compound may be polymerized to form a repeat unit represented by the following Formula B.

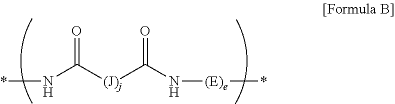

In Formula B, E, J, e, and j are as described above.

For example, the diamine compound and the dicarbonyl compound may be polymerized to form amide repeat units represented by the following Formulae B-1 and B-2.

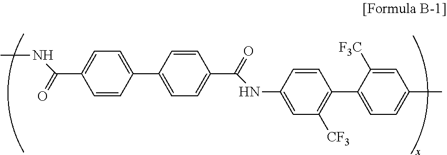

In Formula B-1, x is an integer of 1 to 400.

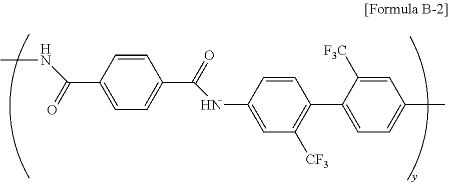

In Formula B-2, y is an integer of 1 to 400.

### Polyester-Based Film

As another example, the base film may comprise a polyester-based resin. Specifically, the base film may be a transparent polyester-based film.

The polyester-based resin may be a homopolymer resin or a copolymer resin in which a dicarboxylic acid and a diol are polycondensed. In addition, the polyester-based resin may be a blend resin in which the homopolymer resins or the copolymer resins are mixed.

Examples of the dicarboxylic acid include terephthalic acid, isophthalic acid, orthophthalic acid, 2,5-naphthalene dicarboxylic acid, 2,6-naphthalene dicarboxylic acid, 1,4-naphthalene dicarboxylic acid, 1,5-naphthalene dicarboxylic acid, diphenyl dicarboxylic acid, diphenoxyethane dicarboxylic acid, diphenyl sulfone dicarboxylic acid, anthracene dicarboxylic acid, 1,3-cyclopentane dicarboxylic acid, 1,3-cyclohexane dicarboxylic acid, 1,4-cyclohexane dicarboxylic acid, hexahydroterephthalic acid, hexahydroisophthalic acid, malonic acid, dimethyl malonic acid, succinic acid, 3,3-diethyl succinic acid, glutaric acid, 2,2-dimethylglutaric acid, adipic acid, 2-methyladipic acid, pimelic acid, azelaic acid, sebacic acid, suberic acid, dodecadicarboxylic acid, and the like.

In addition, examples of the diol include ethylene glycol, propylene glycol, hexamethylene glycol, neopentyl glycol, 1,2-cyclohexanedimethanol, 1,4-cyclohexanedimethanol, decamethylene glycol, 1,3-propanediol, 1,4-butanediol, 1,5-pentanediol, 1,6-hexanediol, 2,2-bis(4-hydroxyphenyl)propane, bis(4-hydroxyphenyl) sulfone, and the like.

Preferably, the polyester-based resin may be an aromatic polyester-based resin having excellent crystallinity. For example, it may have a polyethylene terephthalate (PET) resin as a main component.

When the base film is a polyester-based film, the polyester-based film may comprise a polyester-based resin, specifically a PET resin in an amount of about 85% by weight or more, more specifically, 90% by weight or more, 95% by weight or more, or 99% by weight or more. As another example, the polyester-based film may further comprise a polyester-based resin other than the PET resin. Specifically, the polyester-based film may further comprise up to about 15% by weight of a polyethylene naphthalate (PEN) resin. More specifically, the polyester-based film may further comprise a PEN resin in an amount of about 0.1% by weight to 10% by weight or about 0.1% by weight to 5% by weight.

The polyester-based film having the above composition may have increased crystallinity and enhanced mechanical properties in terms of tensile strength and the like in the process of preparing the same through heating, stretching, and the like.

The base film may have an in-plane retardation (Ro) of 600 nm or less, 500 nm or less, 400 nm or less, 300 nm or less, or 200 nm or less. Within the above range, the occurrence of rainbow stains can be minimized.

In addition, the base film may have a minimum in-plane retardation (Roₘᵢₙ) of 200 nm or less or 150 nm or less. Specifically, the minimum in-plane retardation of the base film may be 120 nm or less, 100 nm or less, 85 nm or less, 75 nm or less, or 65 nm or less.

Meanwhile, the lower limit of the in-plane retardation of the base film may be 0 nm. Alternatively, the lower limit of the in-plane retardation (Ro) may be 10 nm or more, 30 nm or more, or 50 nm or more, in order to balance the optical characteristics and the mechanical properties.

In addition, the base film may have a thickness direction retardation (Rth) of 4,000 nm or more, 5,000 nm or more, or 5,500 nm or more.

In addition, the base film may have a maximum thickness direction retardation (Rthₘₐₓ) of 6,000 nm or more, for example, 6,500 nm or more, for example, 7,500 nm or more, for example, 8,000 nm or more, for example, 8,500 nm or more.

The thickness direction retardation may be a value measured based on a thickness of 40 μm to 50 μm. Within the above range, the degree of orientation of molecules is high, which promotes crystallization and is preferable from the viewpoint of mechanical properties. In addition, as the thickness direction retardation (Rth) is larger, the ratio (Rth/Ro) of the thickness direction retardation (Rth) to the in-plane retardation (Ro) becomes larger, thereby effectively suppressing rainbow stains.

Meanwhile, the upper limit of the thickness direction retardation (Rth) may be 16,000 nm or less, 15,000 nm or less, or 14,000 nm or less, in view of the thickness limit and cost for eliminating rainbow striae in the base film.

Here, the in-plane retardation (Ro) is a parameter defined by a product (Δnxy×d) of anisotropy (Δnxy=|nx−ny|) of refractive indices of two mutually perpendicular axes on a film and the film thickness (d), which is a measure of the degree of optical isotropy and anisotropy. In addition, the minimum in-plane retardation (Roₘᵢₙ) refers to the lowest value when the in-plane retardation (Ro) is measured at a plurality of points in the plane of a film.

In addition, the thickness direction retardation is a parameter defined by a product of an average of the two birefringences Δnxz (=|nx−nz|) and Δnyz (=|ny−nz|) observed on a cross-section in the film thickness direction and the film thickness (d). In addition, the maximum thickness direction retardation (Rthₘₐₓ) refers to the highest value when the thickness direction retardation (Rth) is measured at a plurality of points in the plane of a film.

In addition, the base film may have a ratio (Rth/Ro) of the thickness direction retardation (Rth) to the in-plane retardation (Ro) of 10 or more, 15 or more, or 20 or more. The smaller the in-plane retardation (Ro) and the larger the thickness direction retardation (Rth), the more advantageous for preventing rainbow stains. Thus, it is preferable that the ratio (Rth/Ro) of the two values is maintained to be larger. In particular, the base film may have a ratio (Rthₘₐₓ/Roₘᵢₙ) of the maximum thickness direction retardation (Rthₘₐₓ) to the minimum in-plane retardation (Roₘᵢₙ) of 30 or more, 40 or more, 50 or more, or 60 or more.

The process for preparing the base film may comprise (1) extruding a composition comprising a polyester-based resin to obtain an unstretched film; (2) stretching the unstretched film in the longitudinal direction and in the transverse direction; and (3) heat-setting the stretched film.

In the above preparation process, the base film is prepared by extruding a raw resin and subjecting it to preheating, stretching, and heat setting. In such an event, the composition of the polyester-based resin used as a raw material of the base film is as described above. In addition, the extrusion may be carried out at a temperature of 230° C. to 300° C. or 250° C. to 280° C.

The base film is preheated at a certain temperature before stretching thereof. The preheating temperature satisfies the range of Tg+5° C. to Tg+50° C. based on the glass transition temperature (Tg) of the polyester-based resin, and it is determined to satisfy the range of 70° C. to 90° C. at the same time. Within the above range, the base film may be soft enough to be readily stretched, and it is possible to effectively prevent the phenomenon of breakage during stretching thereof as well.

The stretching is carried out by biaxial stretching. For example, it may be carried out in the transverse direction (or tenter direction, TD) and in the longitudinal direction (or machine direction, MD) through a simultaneous biaxial stretching method or a sequential biaxial stretching method. Preferably, it may be carried out by a sequential biaxial stretching method in which stretching is first performed in one direction, and then stretching is performed in the direction perpendicular thereto.

The stretching ratio in the longitudinal direction may be in a range of 2.0 to 5.0, more specifically 2.8 to 3.5. In addition, the stretching ratio in the transverse direction may be in a range of 2.0 to 5.0, more specifically 2.9 to 3.7. Preferably, the longitudinal stretch ratio (d1) and the transverse stretch ratio (d2) are similar to each other. Specifically, the ratio (d2/d1) of the stretching ratio (d2) in the longitudinal direction to the stretching ratio (d1) in the transverse direction may be 0.5 to 1.0, 0.7 to 1.0, or 0.9 to 1.0. The stretching ratios (d1 and d2) each refer to the ratio that represents the length after stretching as compared with the length before stretching being 1.0. In addition, the stretching speed may be 6.5 m/min to 8.5 m/min, but it is not particularly limited thereto.

The stretched sheet may be heat-set at 150° C. to 250° C., more specifically 160° C. to 230° C. The heat setting may be carried out for 5 seconds to 1 minute, more specifically for 10 seconds to 45 seconds.

After the heat setting is initiated, the sheet may be relaxed in the longitudinal direction and/or in the transverse direction, and the temperature range therefor may be 150° C. to 250° C.

A laminate film comprising a polyester-based film according to an embodiment as a base film may simultaneously enhance surface hardness and elasticity.

The laminate film according to an embodiment may have a Martens hardness of, for example, 170 N/mm² or more, 175 N/mm² or more, 180 N/mm² or more, 181.25 N/mm2 or more, or 185 N/mm² or more, and 250 N/mm² or less, 200 N/mm² or less, 195 N/mm² or less, or 190 N/mm² or less. As a specific example, the laminate film may have a Martens hardness (HM) of 175 N/mm² or more, more specifically, 175 N/mm² to 200 N/mm², when measured for the surface of the hard coating layer by a nanoindentation test according to the ISO 14577-1:2002(E) standard.

In addition, the laminate film may have an HV increase (N/mm²), as calculated by the following equation, of 5 N/mm² or more, specifically, 7 N/mm² or more or 10 N/mm² or more, as a more specific example, 5 N/mm² to 25 N/mm².

$$HM increase ( N / {mm}^{2} ) = HM 1 ( N / {mm}^{2} ) - HM 2 ( N / {mm}^{2} )$$

Here, HV1 is the Martens hardness (HM) (N/mm²) of the laminate film, and HV2 is the Martens hardness (HM) (N/mm²) of a film having a layer structure excluding the hard coating layer from the laminate film.

The laminate film according to an embodiment may have a Vickers hardness (HV) of, for example, 20 N/mm² or more, 25 N/mm² or more, 29 N/mm² or more, or 30 N/mm² or more, and 50 N/mm² or less, 45 N/mm² or less, 40 N/mm² or less, or 35 N/mm² or less. As a specific example, the laminate film may have a Vickers hardness (HV) of 29 N/mm² or more, more specifically, 29 N/mm² to 50 N/mm², when measured for the surface of the hard coating layer by a nanoindentation test according to the ISO 14577-1:2002(E) standard.

In addition, the laminate film may have an HV increase (N/mm²), as calculated by the following equation, of 1.5 N/mm² or more, specifically, 2.0 N/mm² or more or 2.5 N/mm² or more, as a more specific example, 1.5 N/mm² to 7.0 N/mm².

$$HV increase ( N / {mm}^{2} ) = HV 1 ( N / {mm}^{2} ) - HV 2 ( N / {mm}^{2} )$$

Here, HV1 is the Vickers hardness (HV) (N/mm²) of the laminate film, and HV2 is the Vickers hardness (HV) (N/mm²) of a film having a layer structure excluding the hard coating layer from the laminate film.

The laminate film according to an embodiment may have an indentation hardness (H_{IT}) of, for example, 250 N/mm² or more, 270 N/mm² or more, 290 N/mm² or more, 310 N/mm² or more, 320 N/mm² or more, or 330 N/mm² or more, and 500 N/mm² or less, 450 N/mm² or less, 400 N/mm² or less, or 370 N/mm² or less. As a specific example, the laminate film may have an indentation hardness (H_{IT}) of 310 N/mm² or more, more specifically, 310 N/mm² to 450 N/mm², when measured for the surface of the hard coating layer by a nanoindentation test according to the ISO 14577-1:2002(E) standard. Within the above indentation hardness (H_{IT}) range, plastic properties such as impact resistance are exerted, making it advantageous for the application as a cover window of a display device.

In addition, the laminate film may have an H_{IT} increase (N/mm²), as calculated by the following equation, of 10 N/mm² or more, specifically, 15 N/mm² or more, 20 N/mm² or more, or 25 N/mm² or more, as a more specific example, 10 N/mm² to 70 N/mm².

$${H}_{IT} increase ( N / {mm}^{2} ) = {H}_{IT} 1 ( N / {mm}^{2} ) - {H}_{IT} 2 ( N / {mm}^{2} )$$

Here, H_{IT}1 is the indentation hardness (H_{IT}) (N/mm²) of the laminate film, and H_{IT}2 is the indentation hardness (H_{IT}) (N/mm²) of a film having a layer structure excluding the hard coating layer from the laminate film.

The indentation modulus (E_{IT}) of the laminate film according to an embodiment may be, for example, 2,500 MPa or more, 2,800 MPa or more, 2,900 MPa or more, 2,935 MPa or more, or 2,950 MPa or more, and 4,000 MPa or less, 3,500 MPa or less, 3,300 MPa or less, or 3,100 MPa or less. As a specific example, the laminate film may have an indentation modulus (E_{IT}) of 2,900 MPa or more, more specifically, 2,900 MPa to 4,000 MPa, when measured for the surface of the hard coating layer by a nanoindentation test according to the ISO 14577-1:2002(E) standard.

The indentation creep (C_{IT}) of the laminate film according to an embodiment may be, for example, 3.0% or more, 3.5% or more, 3.7% or more, 4.0% or more, or 4.1% or more, and 6.0% or less, 5.5% or less, 5.0% or less, 4.5% or less, or 4.3% or less. As a specific example, the laminate film may have an indentation creep (C_{IT}) of 3.5% or more, more specifically, 3.5% to 5.0%, when measured for the surface of the hard coating layer by a nanoindentation test according to the ISO 14577-1:2002(E) standard.

The recovery relation (η_{IT}) of the laminate film according to an embodiment may be, for example, 50% or more, 55% or more, 60% or more, 61% or more, 63% or more, or 63.5% or more, and 85% or less, 80% or less, 75% or less, or 70% or less. As a specific example, the laminate film may have a recovery relation (η_{IT}) of 63.6% or more, more specifically, 63.6% to 75%, when measured for the surface of the hard coating layer by a nanoindentation test according to the ISO 14577-1:2002(E) standard.

The recovery of the laminate film according to an embodiment may be, for example, 60% or more, 65% or more, 70% or more, or 73.35% or more, and 90% or less, 85% or less, 80% or less, or 75% or less. As a specific example, the laminate film may have a recovery of 65% or more, more specifically, 65% to 90%, when measured for the surface of the hard coating layer by a nanoindentation test according to the ISO 14577-1:2002(E) standard. The recovery may be calculated by the following equation.

$$Recovery ( \% ) = [ ( {h}_{m ax ( at 30 mN )} - {h}_{p} ) / {h}_{m ax ( at 30 mN )} ] \times 100$$

Here, hₘₐₓ (at 30 mN) is the maximum indentation depth (μm) during which the surface of the hard coating layer is pressed downward for 15 seconds at a force of 30 mN and held (crept) for 5 seconds, and hₚ is the depth (μm) of the indentation that remains unrecovered even after the force is released.

In addition, the laminate film may have a recovery increase (%), as calculated by the following equation, of 5% or more, specifically, 8% or more or 9% or more, as a more specific example, 5% to 15%.

$$Recovery increase ( \% ) = Recovery 1 ( \% ) - Recovery 2 ( \% )$$

Here, Recovery1 is the recovery (%) of the laminate film, and Recoveiy2 is the recovery (%) of a film having a layer structure excluding the hard coating layer from the laminate film.

### Hard Coating Layer (200)

The hard coating layer (200) is disposed on one side of the base film (100).

The hard coating layer may have an upper side and a lower side, of which the lower side may face the base film, and the upper side may be the outermost side exposed to the outside. In addition, the lower side of the hard coating layer may be in direct contact with one side of the base film or may be bonded to one side of the base film through an additional coating layer. As an example, the hard coating layer may be directly formed on one side of the base film.

The hard coating layer may enhance the mechanical properties and/or optical properties of the laminate film. In addition, the hard coating layer may further comprise antiglare, antifouling, antistatic functions, and the like.

The hard coating layer may comprise at least one of an organic component, an inorganic component, and an organic-inorganic composite component as a hard coating agent.

As an example, the hard coating layer may comprise an organic resin. Specifically, the organic resin may be a curable resin. Thus, the hard coating layer may be a curable coating layer. In addition, the organic resin may be a binder resin.

Specifically, the hard coating layer may comprise at least one selected from the group consisting of a urethane acrylate-based compound, an acrylic ester-based compound, an acrylate-based compound, and an epoxy acrylate-based compound. More specifically, the hard coating layer may comprise a urethane acrylate-based compound and an acrylic ester-based compound. Even more specifically, the hard coating layer may comprise a urethane acrylate-based compound, an acrylic ester-based compound, and an acrylate-based compound, but it is not limited thereto.

The urethane acrylate-based compound may comprise a urethane bond as a repeat unit and may have a plurality of functional groups.

The urethane acrylate-based compound may be one in which a terminal of a urethane compound formed by reacting a diisocyanate compound with a polyol is substituted with an acrylate group. For example, the diisocyanate compound may comprise at least one of a linear, branched, or cyclic aliphatic diisocyanate compound having 4 to 12 carbon atoms and an aromatic diisocyanate compound having 6 to 20 carbon atoms. The polyol comprises 2 to 4 hydroxyl (—OH) groups and may be a linear, branched, or cyclic aliphatic polyol compound having 4 to 12 carbon atoms or an aromatic polyol compound having 6 to 20 carbon atoms. The terminal substitution with an acrylate group may be carried out by an acrylate-based compound having a functional group capable of reacting with an isocyanate group (—NCO). For example, an acrylate-based compound having a hydroxyl group or an amine group may be used, and a hydroxyalkyl acrylate or aminoalkyl acrylate having 2 to 10 carbon atoms may be used.

The urethane acrylate-based compound may contain 2 to 15 functional groups.

Examples of the urethane acrylate-based compound include a bifunctional urethane acrylate oligomer having a weight average molecular weight of 1,400 to 25,000, a trifunctional urethane acrylate oligomer having a weight average molecular weight of 1,700 to 16,000, a tetra-functional urethane acrylate oligomer having a weight average molecular weight of 500 to 2,000, a hexa-functional urethane acrylate oligomer having a weight average molecular weight of 818 to 2,600, an ennea-functional urethane acrylate oligomer having a weight average molecular weight of 2,500 to 5,500, a deca-functional urethane acrylate oligomer having a weight average molecular weight of 3,200 to 3,900, and a pentakaideca-functional urethane acrylate oligomer having a weight average molecular weight of 2,300 to 20,000, but it is not limited thereto.

The urethane acrylate-based compound may have a glass transition temperature (Tg) of −80° C. to 100° C., −80° C. to 90° C., −80° C. to 80° C., −80° C. to 70° C., −80° C. to 60° C., −70° C. to 100° C., −70° C. to 90° C., −70° C. to 80° C., −70° C. to 70° C., −70° C. to 60° C., −60° C. to 100° C., −60° C. to 90° C., −60° C. to 80° C., −60° C. to 70° C., −60° C. to 60° C., −50° C. to 100° C., −50° C. to 90° C., −50° C. to 80° C., −50° C. to 70° C., or −50° C. to 60° C.

The acrylic ester-based compound may be at least one selected from the group consisting of a substituted or unsubstituted acrylate and a substituted or unsubstituted methacrylate. The acrylic ester-based compound may contain 1 to 10 functional groups.

Examples of the acrylic ester-based compound include trimethylolpropane triacrylate (TMPTA), trimethylolpropaneethoxy triacrylate (TMPEOTA), glycerin propoxylated triacrylate (GPTA), pentaerythritol tetraacrylate (PETA), and dipentaerythritol hexaacrylate (DPHA), but it is not limited thereto.

The acrylic ester-based compound may have a weight average molecular weight of 500 to 6,000, 500 to 5,000, 500 to 4,000, 1,000 to 6,000, 1,000 to 5,000, 1,000 to 4,000, 1500 to 6,000, 1,500 to 5,000, or 1,500 to 4,000. The acrylic ester-based compound may have an acrylate equivalent of 50 g/eq. to 300 g/eq., 50 g/eq. to 200 g/eq., or 50 g/eq. to 150 g/eq.

The acrylate-based compound may contain 1 to 10 functional groups. Examples of the acrylate-based compound include a monofunctional acrylate oligomer having a weight average molecular weight of 100 to 300, a bifunctional acrylate oligomer having a weight average molecular weight of 250 to 2,000, and an acrylate oligomer having a weight average molecular weight of 1,000 to 3,000, but it is not limited thereto.

The epoxy acrylate-based compound may contain 1 to 10 functional groups. Examples of the epoxy acrylate-based compound include a monofunctional epoxy acrylate oligomer having a weight average molecular weight of 100 to 300, a bifunctional epoxy acrylate oligomer having a weight average molecular weight of 250 to 2,000, and a tetra-functional epoxy acrylate oligomer having a weight average molecular weight of 1,000 to 3,000, but it is not limited thereto. The epoxy acrylate-based compound may have an epoxy equivalent of 50 g/eq. to 300 g/eq., 50 g/eq. to 200 g/eq., or 50 g/eq. to 150 g/eq.

The content of the organic resin may be 30% by weight to 100% by weight based on the total weight of the hard coating layer. Specifically, the content of the organic resin may be 40% by weight to 90% by weight, or 50% by weight to 80% by weight, based on the total weight of the hard coating layer.

The hard coating layer may optionally further comprise a filler. The filler may be, for example, inorganic particles. Examples of the filler include silica, barium sulfate, zinc oxide, and alumina. The filler may have a particle diameter of 1 nm to 100 nm. Specifically, the particle diameter of the filler may be 5 nm to 50 nm or 10 nm to 30 nm. The filler may comprise inorganic fillers having particle size distributions different from each other. For example, the filler may comprise a first inorganic filler having a D50 of 20 nm to 35 nm and a second inorganic filler having a D50 of 40 nm to 130 nm. The content of the filler may be 25% by weight or more, 30% by weight or more, or 35% by weight or more, based on the total weight of the hard coating layer. In addition, the content of the filler may be 50% by weight or less, 45% by weight or less, or 40% by weight or less, based on the total weight of the hard coating layer. Preferably, the hard coating layer may not comprise an inorganic filler such as silica. In such a case, for example, the adhesion between the base film and the hard coating layer of the composition described above may be enhanced.

The hard coating layer may further comprise a photoinitiator. Examples of the photoinitiator include 1-hydroxy-cyclohexyl-phenyl ketone, 2-hydroxy-2-methyl-1-phenyl-1-propanone, 2-hydroxy-1-[4-(2-hydroxyethoxy)phenyl]-2-methyl-1-propanone, methylbenzoylformate, α,α-dimethoxy-α-phenylacetophenone, 2-benzoyl-2-(dimethylamino)-1-[4-(4-morpholinyl)phenyl]-1-butanone, 2-methyl-1-[4-(methylthio)phenyl]-2-(4-morpholinyl)-1-propanone diphenyl(2,4,6-trimethylbenzoyl)-phosphine oxide, and bis(2,4,6-trimethylbenzoyl)-phenylphosphine oxide, but it is not limited thereto. In addition, commercially available products include Irgacure 184, Irgacure 500, Irgacure 651, Irgacure 369, Irgacure 907, Darocur 1173, Darocur MBF, Irgacure 819, Darocur TPO, Irgacure 907, and Esacure KIP 100F. The photoinitiator may be used alone or in combination of two or more different types.

The hard coating layer may further comprise an antifouling agent. For example, the hard coating layer may comprise a fluorine-based compound. The fluorine-based compound may have an antifouling function. Specifically, the fluorine-based compound may be an acrylate-based compound having a perfluorine-based alkyl group. Specific examples thereof may include perfluorohexylethyl acrylate, but it is not limited thereto.

The hard coating layer may further comprise an antistatic agent. The antistatic agent may comprise an ionic surfactant. For example, the ionic surfactant may comprise an ammonium salt or a quaternary alkylammonium salt, and the ammonium salt and the quaternary alkylammonium salt may comprise a halide such as a chloride or a bromide.

In addition, the hard coating layer may further comprise additives such as surfactants, UV absorbers, UV stabilizers, anti-yellowing agents, leveling agents, and dyes to improve color values. For example, the surfactant may be a monofunctional to bifunctional fluorine-based acrylate, a fluorine-based surfactant, or a silicone-based surfactant. The surfactant may be employed in a form dispersed or crosslinked in the hard coating layer. In addition, examples of the UV absorber include benzophenone-based compounds, benzotriazole-based compounds, and triazine-based compounds. Examples of the UV stabilizer include tetramethyl piperidine and the like. The content of the additives may be variously adjusted within a range that does not impair the physical properties of the hard coating layer. For example, the content of the additives may be 0.01 to 10% by weight based on the weight of the hard coating layer, but it is not limited thereto.

The hard coating layer may be composed of a single layer or two or more layers. As an example, the hard coating layer is formed as a single layer and can simultaneously increase the durability of the laminate film and function as anti-fingerprint or anti-contamination.

The hard coating layer may have a thickness of 2 μm or more, 3 μm or more, 5 μm or more, or 10 μm or more, and 50 μm or less, 30 μm or less, 20 μm or less, or 10 μm or less. For example, the thickness of the hard coating layer may be 2 μm to 20 μm. Specifically, the thickness of the hard coating layer may be 5 μm to 20 μm. If the thickness of the hard coating layer is too thin, it may not have sufficient surface hardness to protect the base film, so that the durability of the laminate film may be deteriorated. If it is too thick, the flexibility of the laminate film may be deteriorated, and the overall thickness of the laminate film may be increased, which may be disadvantageous for forming a thin film.

Accordingly, the hard coating layer may be formed from a hard coating composition comprising at least one of an organic-based composition, an inorganic-based composition, and an organic-inorganic composite composition. For example, the hard coating composition may comprise at least one of an acrylate-based compound, a siloxane compound, and a silsesquioxane compound. In addition, the hard coating layer may further comprise inorganic particles. As a specific example, the hard coating layer may be formed from a hard coating composition comprising a urethane acrylate-based compound, an acrylic ester-based compound, and a fluorine-based compound.

The hard coating layer may be formed by applying a hard coating composition on the base film, followed by drying and curing thereof.

The hard coating composition may comprise the organic resin, photoinitiator, antifouling additive, antistatic agent, other additives and/or solvents described above.

Examples of the organic solvent include alcohol-based solvents such as methanol, ethanol, isopropyl alcohol, and butanol; alkoxy alcohol-based solvents such as 2-methoxyethanol, 2-ethoxyethanol, and 1-methoxy-2-propanol; ketone-based solvents such as acetone, methyl ethyl ketone, methyl isobutyl ketone, methyl propyl ketone, and cyclohexanone; ether-based solvents such as propylene glycol monopropyl ether, propylene glycol monomethyl ether, ethylene glycol monoethyl ether, ethylene glycol monopropyl ether, ethylene glycol monobutyl ether, diethylene glycol monomethyl ether, diethyl glycol monoethyl ether, diethylene glycol monopropyl ether, diethylene glycol monobutyl ether, and diethylene glycol-2-ethylhexyl ether; and aromatic solvents such as benzene, toluene, and xylene, which may be used alone or in combination thereof.

The content of the organic solvent is not particularly limited since it may be variously adjusted within a range that does not impair the physical properties of the hard coating composition. The organic solvent may be employed such that the weight ratio of the solids content of the components contained in the coating composition to the organic solvent may be about 30:70 to about 99:1. If the content of the organic solvent is within the above range, the composition may have appropriate flowability and coatability.

The hard coating composition may comprise 10% by weight to 30% by weight of an organic resin, 0.1% by weight to 5% by weight of a photoinitiator, 0.01% by weight to 2% by weight of an antifouling agent, and 0.1% by weight to 10% by weight of an antistatic agent. According to the composition, the mechanical properties and antifouling and antistatic characteristics of the hard coating layer may be enhanced together.

The hard coating composition may be coated on the base film by a bar coating method, a knife coating method, a roll coating method, a blade coating method, a die coating method, a microgravure coating method, a comma coating method, a slot die coating method, a lip coating method, or a solution casting method.

Thereafter, the organic solvent contained in the hard coating composition may be removed through a drying step. The drying step may be carried out at a temperature of 40° C. to 100° C., preferably 40° C. to 80° C., 50° C. to 100° C., or 50° C. to 80° C., for about 1 minute to 20 minutes, preferably 1 minute to 10 minutes or 1 minute to 5 minutes.

Thereafter, the hard coating composition layer may be cured by light and/or heat.

### Elastic Layer (300)

The elastic layer (300) comprises a polyether-block-amide (PEBA).

The polyether-block-amide comprises two phases: a polyamide segment, which is a rigid segment, and a polyether segment, which is a soft segment.

The rigid segment may be a crystalline segment or a semi-crystalline segment. The soft segment may be an amorphous segment. For example, the amorphous segment may be a matrix, and the crystalline segment may be distributed in the matrix.

As the polyether-block-amide comprises both a rigid segment and a soft segment together, the elastic layer can have relatively strong mechanical strength and, at the same time, have flexible and/or elastomer characteristics.

The elastic layer may have relatively strong mechanical strength and, at the same time, have flexible and/or elastomer characteristics.

The polyamide segment may have a melting point of about 80° C. or higher, specifically, about 130° C. to 180° C. It is a substantially crystalline phase that constitutes the hard segment. In addition, the polyether segment may have a glass transition temperature of about −40° C. or lower, specifically −80° C. to −40° C. It is present in a low temperature region and may constitute a substantially amorphous soft segment.

The polyether-block-amide may be one in which a polyamide containing two or more carboxyl groups in the molecule and an ether containing two or more hydroxyl groups are combined in the molecule.

The elastic layer may comprise a polyether-block-amide. The polyether-block-amide may comprise at least one copolymer comprising a polyether block and a polyamide block. The polyether-block-amide thus comprises at least one polyether block and at least one polyamide block.

A copolymer (polyether-block-amide) comprising a polyether block and a polyamide block may be one in which a polyether block containing a reactive end and a polyamide block containing a reactive end are polycondensed.

As an example, the polyether-block-amide may be a polycondensed polymer comprising a polyamide block containing a diamine end and a polyoxyalkylene block containing a dicarboxyl end.

As another example, the polyether-block-amide may be a polycondensed polymer comprising a polyamide block containing a dicarboxyl end and a polyoxyalkylene block containing a diamine end.

The polyoxyalkylene block may be obtained by a cyanoethylation reaction and a hydrogenation reaction of an aliphatic α,ω-dihydroxylated polyoxyalkylene block known as polyetherdiol.

The polyether-block-amide may be a polycondensed polymer comprising a polyamide block containing a dicarboxyl end and a polyetherdiol block. In such an event, the polyether-block-amide is a polyetheresteramide.

As an example, a polyamide block comprising a dicarboxylic chain end may comprise a polycondensed polymer of a polyamide precursor in the presence of a chain-limiting dicarboxylic acid.

As an example, a polyamide block comprising a diamine chain end may comprise a polycondensed polymer of a polyamide precursor in the presence of a chain-limiting diamine.

As an example, a polyamide block comprising a dicarboxylic chain end may comprise a polycondensed polymer of an α,ω-aminocarboxylic acid, lactam, or dicarboxylic acid and a diamine in the presence of a chain-limiting dicarboxylic acid.

Polyamide 12 or polyamide 6 is preferred as the polyamide block.

The polyether-block-polyamide may comprise blocks with randomly distributed unit structures.

Advantageously, the following three types of polyamide blocks may be adopted.

As a first type, the polyamide block may comprise a polycondensed polymer of a carboxylic acid and an aliphatic or aryl aliphatic diamine. The carboxylic acid may have 4 to 20 carbon atoms, preferably 6 to 18 carbon atoms. The aliphatic or aryl aliphatic diamine may have 2 to 20 carbon atoms, preferably 6 to 14 carbon atoms.

The carboxylic acid, specifically dicarboxylic acid, may be, for example, 1,4-cyclohexanedicarboxylic acid, 1,2-cyclohexyldicarboxylic acid, 1,4-butanedioic acid, adipic acid, azelaic acid, suberic acid, sebacic acid, 1,12-dodecanedicarboxylic acid, 1,14-tetradecanedicarboxylic acid, 1,18-octadecanedicarboxylic acid, terephthalic acid, isophthalic acid, naphthalenedicarboxylic acid, and dimerized fatty acid.

The diamine may be, for example, 1,5-tetramethylenediamine, 1,6-hexamethylenediamine, 1,10-decamethylenediamine, 1,12-dodecamethylenediamine, trimethyl-1,6-hexamethylenediamine, 2-methyl-1,5-pentamethylenediamine, isomers of bis(3-methyl-4-aminocyclohexyl)methane (BMACM), 2,2-bis(3-methyl-4-aminocyclohexyl)propane (BMACP), (bis(para-aminocyclohexyl)methane (PACM), isophoronediamine (IPD), 2,6-bis(aminomethyl)norbornane (BAMN), piperazine (Pip), meta-xylylenediamine (MXD), and para-xylylenediamine (PXD).

Specifically, the first type of the polyamide block may comprise PA 412, PA 414, PA 418, PA 610, PA 612, PA 614, PA 618, PA 912, PA 1010, PA 1012, PA 1014, PA 1018, MXD6, PXD6, MXD10, or PXD10.

As a second type, the polyamide block may comprise a polycondensed polymer of at least one α,ω-aminocarboxylic acid and/or at least one lactam each having 6 to 12 carbon atoms in the presence of a dicarboxylic acid or a diamine having 4 to 12 carbon atoms. Examples of the lactam include caprolactam, oenantholactam, and lauryllactam. Examples of the α,ω-aminocarboxylic acid include aminocaproic acid, 7-aminoheptanoic acid, 11-aminoundecanoic acid, and 12-aminododecanoic acid. Specifically, the second type of the polyamide block may comprise polyamide 11, polyamide 12, or polyamide 6.

As a third type, the polyamide block may comprise a polycondensed polymer of at least one α,ω-aminocarboxylic acid (or at least one lactam), at least one diamine, and at least one dicarboxylic acid. In such an event, the polyamide (PA) block may be prepared by polycondensation of a diamine, a diacid, and a comonomer (or comonomers) as follows.

As the diamine, for example, a linear aliphatic diamine, an aromatic diamine, or the like be employed. As the diacid, for example, an alicyclic dibasic acid, an aliphatic dibasic acid, an aromatic dibasic acid, or the like may be employed. As the diacid, for example, a dicarboxylic acid may be employed. The comonomer may be selected from lactams, α,ω-aminocarboxylic acids, and mixtures comprising substantially equal moles of one or more diamines and one or more dicarboxylic acids. The comonomer may be employed in an amount of 50% by weight or less, preferably 20% by weight or less, advantageously 10% by weight or less, based on the total of the combined polyamide precursor monomers.

The polycondensation reaction according to the third type may be carried out in the presence of a chain-limiting agent selected from dicarboxylic acids. Specifically, a dicarboxylic acid may be used as a chain-limiting agent, and the dicarboxylic acid may be introduced in a stoichiometric excess relative to the one or more diamines.

In an alternative form of the third type, the polyamide block may comprise a polycondensed polymer of at least two α,ω-aminocarboxylic acids having 6 to 12 carbon atoms, or at least two lactams, or lactams and aminocarboxylic acids with different numbers of carbon atoms, optionally in the presence of a chain-limiting agent. The aliphatic α,ω-aminocarboxylic acid may be, for example, aminocaproic acid, 7-aminoheptanoic acid, 11-aminoundecanoic acid, or 12-aminododecanoic acid. The lactam may be, for example, caprolactam, oenantholactam, or lauryllactam.

The aliphatic diamine may be, for example, hexamethylenediamine, dodecamethylene-diamine, or trimethylhexamethylenediamine.

The alicyclic diacid may be, for example, 1,4-cyclohexanedicarboxylic acid. In addition, the aliphatic diacid may be, for example, butanedioic acid, adipic acid, azelaic acid, suberic acid, sebacic acid, dodecanedicarboxylic acid, dimer fatty acids (preferably, dimer ratio of 98% or more; preferably hydrogenated; sold under the trade name Pripol by Unigema or Empol by Henkel), or polyoxyalkylene-α,ω-diacid.

The aromatic diacid may be, for example, terephthalic acid or isophthalic acid.

The alicyclic diamine may be, for example, isomers of bis(3-methyl-4-aminocyclohexyl)methane (BMACM) and 2,2-bis(3-methyl-4-aminocyclohexyl)propane (BMACP) or bis(para-aminocyclohexyl)methane (PACM).

Other diamines include, for example, isophorone diamine (IPDI), 2,6-bis(aminomethyl)norbonane (BAMN), and piperazine.

Examples of an aryl aliphatic diamine include meta-xylylenediamine (MXD) and para-xylylene diamine (PXD), but it is not limited thereto.

Examples of the third type of the polyamide block include PA 66/6, PA 66/610/11/12, and the like.

In the PA 66/6, 66 indicates a hexamethylenediamine unit condensed with adipic acid, and 6 indicates a unit introduced by condensation of caprolactam.

In the PA 66/610/11/12, 66 indicates a hexamethylenediamine unit condensed with adipic acid, 610 indicates a hexamethylenediamine unit condensed with sebacic acid, 11 indicates a unit introduced by condensation of aminoundecanoic acid, and 12 indicates a unit introduced by condensation of lauryllactam.

The polyamide block may have a number average molecular weight of 400 to 20,000, specifically 500 to 10,000.

The polyether block may be, for example, at least one polyalkylene ether polyol, for example, polyalkylene ether diol. Specifically, it may be selected from polyethylene glycol (PEG), polypropylene glycol (PPG), polytrimethylene glycol (PO3G), polytetramethylene glycol (PTMG), mixtures thereof, and copolymers thereof.

The polyether block may comprise a polyoxyalkylene unit containing an NH₂ chain end. The unit may be introduced by cyanoacetylating an aliphatic α,ω-dihydroxy polyoxyalkylene unit known as polyetherdiol. Specifically, Jeffamine (e.g., Jeffamine™ D400, D2000, ED2003, or XTJ542 from Huntsman) may be used.

The at least one polyether block comprises, for example, at least one polyether selected from polyalkyleneetherpolyols such as PEG, PPG, PO3G, and PTMG, polyethers containing NH₂ at a chain end and polyoxyalkylene sequences, copolymers in which they are arranged randomly and/or in blocks (ether copolymers), and mixtures thereof.

The polyether block may be employed in an amount of 10 to 80% by weight, specifically, 20 to 60% by weight or 20 to 40% by weight, based on the total weight of the copolymer. The polyether block may have a number average molecular weight of 200 to 1,000, specifically 400 to 800 or 500 to 700.

The polyether block may be introduced from polyethylene glycol, polypropylene glycol, or polytetramethylene glycol.

The polyether block may be copolymerized with a polyamide block containing a carboxyl end to form a polyether-block-amide.

The polyether block may be converted to a polyetherdiamine through amination and then condensed with a polyamide block containing a carboxyl end to form a polyether-block-amide.

The polyether block may be mixed with a polyamide precursor and a chain-limiting agent to form a polyether-block-amide containing statistically dispersed units.

The polyether may be, for example, polyethylene glycol (PEG), polypropylene glycol (PPG), or polytetramethylene glycol (PTMG). Polytetramethylene glycol is also known as polytetrahydrofuran (PTHF). The polyether block may be introduced into the chain of a polyether-block-amide from a diol or diamine form, wherein the polyether blocks are referred to as PEG blocks, PPG blocks, and PTMG blocks, respectively.

In addition, even if the polyether block comprises a unit other than a unit derived from ethylene glycol (—OC₂H₄—), propylene glycol (—O—CH₂—CH(CH₃)—), or tetramethylene glycol (—O—(CH₂)₄—), such a polyether block should be understood as falling within the scope of the embodiment.

The polyamide block may have a number average molecular weight of 300 to 15,000 or 600 to 5,000. The polyether block may have a number average molecular weight of 100 to 6,000, preferably 200 to 3,000.

Specifically, the content of the polyamide block contained in the polyether-block-amide may be 50% by weight or more based on the total polyether-block-amide. This may mean the possibility of statistical distribution within the polymer chain. Specifically, the content of the polyamide block may be 50 to 80% by weight. In addition, the content of the polyether block contained in the polyether-block-amide may be 20 to 50% by weight based on the total polyether-block-amide.

The ratio of number average molecular weights of the polyamide block and the polyether block of the copolymer may be, for example, 1:0.25 to 1:1. Specifically, the number average molecular weight of the polyamide block/the number average molecular weight of the polyether block of the copolymer may be 1,000/1,000, 1,300/650, 2,000/1,000, 2,600/650, or 4,000/1,000.

The polyether-block-amide may be prepared by a two-step method, which comprises a first step of preparing a polyamide block and a polyether block, and a second step of polycondensing the polyamide block and the polyether block to prepare an elastic polyether-block-amide. Alternatively, the polyether-block-amide may be prepared by polycondensation of monomers in a single step.

The polyether-block-amide may have a Shore D hardness of, for example, 20 to 75, specifically 30 to 70.

The polyether-block-amide may have an intrinsic viscosity of 0.8 to 2.5 as measured with metacresol at 25° C. The intrinsic viscosity may be measured according to ISO 307:2019. Specifically, the intrinsic viscosity in a solution may be measured in a metacresol solution with a concentration of 0.5% by weight at 25° C. using an Ubbelohde viscometer.

Examples of the polyether-block-amide include Pebax™ and Pebax™ Rnew™ from Arkema, and VESTAMID™ E from Evonik, but it is not limited thereto.

The optical properties of the elastic layer may be adjusted within a certain range. Thus, it is advantageous for application to a cover window of a display device.

The elastic layer may have a haze of, for example, 3% or less, specifically, 2% or less, 1.5% or less, or 1.2% or less. In addition, the haze of the elastic layer may be 0.010% or more or 0.10% or more.

The elastic layer may have an average visible light transmittance of, for example, 85% or more, specifically, 88% or more or 90% or more. In addition, the average visible light transmittance of the elastic layer may be 99.99% or less.

The elastic layer may have a thickness of 20 μm or more, 30 μm or more, 50 μm or more, or 100 μm or more, and 500 μm or less, 400 μm or less, 300 μm or less, or 200 μm or less. As a specific example, the thickness of the base film may be 20 μm to 500 μm, more specifically 50 μm to 200 μm.

### Display Device

The display device according to an embodiment comprises the laminate film described above in a cover. Specifically, the laminated film may constitute a cover window in the display device.

Referring to FIGS. 1 and 2, the display device (1) according to an embodiment comprises a display panel (20); and a cover window (10) disposed on the front side of the display panel (20), wherein the cover window (10) comprises a base film (100); a hard coating layer (200) disposed on one side of the base film (100); and an elastic layer (300) disposed on the other side of the base film (100), and the elastic layer (300) comprises a polyether-block-amide.

As an example, the base film may comprise a polyimide-based resin. As another example, the base film may comprise a polyester-based resin.

The laminate film contained in the display device has substantially the same structure and characteristics as those of the laminate film described above.

The display device may be flexible. For example, the display device may be a flexible display device. Specifically, it may be a foldable display device. More specifically, the foldable display device may be an in-folding type or an out-folding type depending on the folding direction.

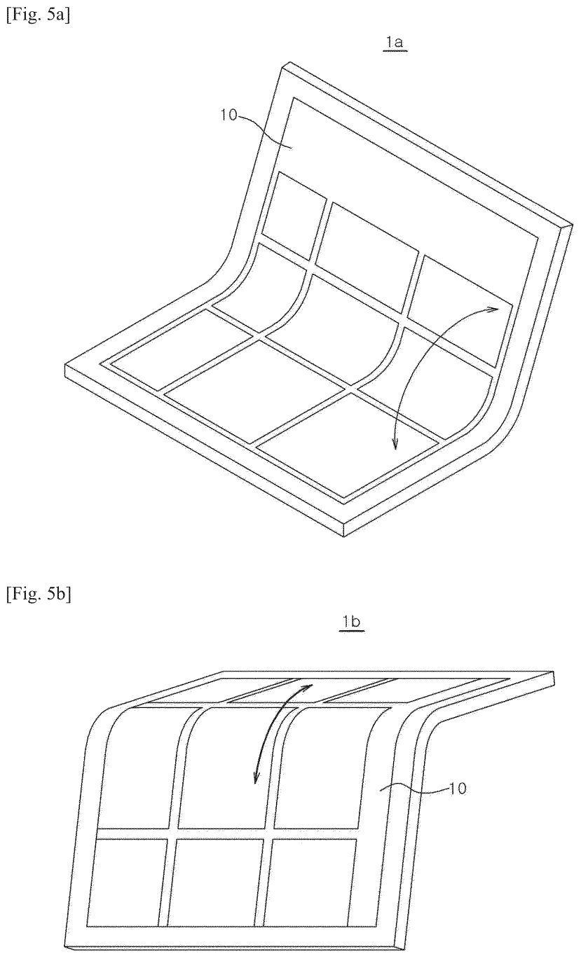

FIGS. 5a and 5b each show in-folding and out-folding type flexible display devices. Referring to FIG. 5a, the display device may be an in-folding type flexible display device (1a) in which the screen is located inside the folding direction. Alternatively, referring to FIG. 5b, the display device may be an out-folding type flexible display device (1b) in which the screen is located outside the folding direction.

Referring to FIG. 1, the display device (1) comprises a cover window (10), a display panel (20), a board (30), and a frame (40) protecting them. The cover window (10) comprises the laminate film as described above.

As an example, the display panel (20) may be a liquid crystal display (LCD) panel. As another example, the display panel (20) may be an organic light emitting display (OLED) panel. The organic light emitting display device may comprise a front polarizing plate and an organic light emitting display panel. The front polarizing plate may be disposed on the front side of the organic light emitting display panel. In more detail, the front polarizing plate may be bonded to the side of the organic light emitting display panel where an image is displayed. The organic light emitting display panel displays an image by self-emission of a pixel unit. The organic light emitting display panel comprises an organic light emitting substrate and a driving substrate. The organic light emitting substrate comprises a plurality of organic light emitting units that correspond to respective pixels. The organic light emitting units each comprise a cathode, an electron transport layer, a light emitting layer, a hole transport layer, and an anode. The driving substrate is operatively coupled to the organic light emitting substrate. That is, the driving substrate may be coupled to the organic light emitting substrate so as to apply a driving signal such as a driving current. More specifically, the driving substrate may drive the organic light emitting substrate by applying a current to each of the organic light emitting units.

In addition, an adhesive layer may be interposed between the cover window (10) and the display panel (20). For example, the adhesive layer may comprise an optically transparent adhesive.

### MODE FOR THE INVENTION

The embodiments described below are provided to help understanding, and the scope of implementation is not limited thereto.

### A. Laminate Film Comprising a Polyimide-Based Film

Various laminate films comprising a polyimide-based film were prepared and evaluated.

### Example A1

### Step (1) Formation of a Hard Coating Layer

A hard coating composition having a composition as shown in Table 1 below was coated on one side of a transparent polyimide-based film (TPI, SKC) having a thickness of 50 μm by a die coating method. Thereafter, it was thermally treated at a temperature of 60° C. for 3 minutes to dry the solvent in the coating layer and cured by irradiating UV light at a dose of 1 J to prepare a hard coating layer having a thickness of about 5 μm.

TABLE 1

| | Component | % by weight |
|---|---|---|
| Solvent | Propylene glycol methyl ether | 22.5 |
| | Methyl isobutyl ketone | 52.5 |
| Binder | Urethane acrylate | 12.9 |
| | Acrylic ester | 3.8 |
| | Acrylate | 7.3 |
| Photoinitiator | 1-Hydroxycyclohexyl phenyl ketone | 0.8 |
| Antifouling additive | Perfluorohexylethyl acrylate | 0.2 |

### Step (2) Lamination of an Elastic Layer

A polyether-block-amide resin (Arkema Pebax™ Rnew™ 72R53, Arkema) was fed to an extruder, melt-blended at about 220° C., extruded to a single layer, and laminated with the base film on which the hard coating layer had been formed to prepare a laminate film with a PEBA layer having a thickness of 50 μm formed on the base film with the hard coating layer.

### Example A2

A laminate film was prepared in the same manner as in Example A1, except that a polyether-block-amide resin (Arkema Pebax™ Rnew™ 55R53, Arkema) was used to prepare a PEBA film in step (2) of Example A1.

### Comparative Example A1

A polyether-block-amide resin (Arkema Pebax™ Rnew™ 72R53, Arkema) was fed to an extruder, melt-blended at about 220° C., extruded to a single layer, and laminated with a transparent polyimide-based film (TPI, SKC) having a thickness of 50 μm to prepare a laminate film with a PEBA layer having a thickness of 50 μm formed on the base film.

### Comparative Example A2

A laminate film was prepared in the same manner as in Comparative Example A1, except that a polyether-block-amide resin (Arkema Pebax™ Rnew™ 55R53, Arkema) was used to prepare a PEBA film.

### Comparative Example A3

The same procedure as in step (1) of Example A1 was repeated to prepare a film with a hard coating layer, except that a transparent polyimide-based film (TPI, SKC) having a thickness of 100 μm was used.

The layer configuration of the films prepared above is summarized in Table 2 below.

TABLE 2

| | Layer configuration |
|---|---|
| Ex. A1 | Hard coating (5 μm) / TPI (50 μm) / PEBA 72R53 (50 μm) |
| Ex. A2 | Hard coating (5 μm) / TPI (50 μm) / PEBA 55R53 (50 μm) |
| C. Ex. A1 | TPI (50 μm) / PEBA 72R53 (50 μm) |
| C. Ex. A2 | TPI (50 μm) / PEBA 55R53 (50 μm) |
| C. Ex. A3 | Hard coating (5 μm) / TPI (100 μm) |

### Test Example A1: Nanoindentation Test

A nanoindentation test was performed on the film samples prepared in the Examples and Comparative Examples. Each film sample was cut into A4 size and stored at 25±5° C. and 50±5% RH until the test without additional pretreatment. Thereafter, each film sample was evaluated using a nanoindentation surface analyzer (FISCHERSCOPE HM2000, FISCHER). Specifically, each laminate film sample was placed on a glass test plate (Fischerscope Part no. 600-028) with a thickness of about 3T as a sample holder such that the surface of the hard coating layer (or the surface of the base film if there was no hard coating layer) was facing upward (i.e., to be the indentation side). Thereafter, the nanoindentation test was carried out in which a diamond tip was pressed downward for 15 seconds at a force of 30 mN at room temperature and held (crept) for five seconds; thereafter, it was raised upward. Vickers hardness (HV), indentation hardness (H_{IT}), recovery, and maximum indentation depth (h_{max (at 30 mN)}) at a maximum force (30 mN) were measured. The nanoindentation test was carried out according to ISO 14577-1:2002(E) and 14577-2:2002(E). In addition, the recovery was calculated by the following equation.

$$Recovery ( \% ) = [ ( {h}_{m ax ( at 30 mN )} - {h}_{p} ) / {h}_{m ax ( at 30 mN )} ] \times 100$$

Here, h_{max (at 30 mN)} is the maximum indentation depth (μm) during which the surface of the hard coating layer was pressed downward for 15 seconds at a force of 30 mN and held (crept) for 5 seconds, and hₚ is the depth (μm) of the indentation that remained unrecovered even after the force was released.

The results are shown in Table 3 below.

TABLE 3

| | HV | H_{IT} | Recovery | h_{max (at 30 mN)} |
|---|---|---|---|---|
| | (N/mm²) | (N/mm²) | (%) | (μm) |
| Ex. A1 | 50.31 | 532.36 | 78.7873 | 2.0683 |
| Ex. A2 | 49.58 | 524.65 | 79.0020 | 2.1014 |
| C. Ex. A1 | 47.63 | 504.06 | 70.8408 | 2.1063 |
| C. Ex. A2 | 46.90 | 496.25 | 71.3095 | 2.1519 |
| C. Ex. A3 | 46.58 | 492.94 | 75.6227 | 2.0852 |

As can be seen from Table 3 above, the films of the Examples were excellent in both surface hardness and restorability, whereas the films of the Comparative Examples were relatively poor in at least one of these characteristics.

### Test Example A2: Optical Properties and Color

Optical properties and color were measured on the film samples. Each film sample was measured for average visible light transmittance according to the ISO 13468 standard and haze according to the ISO 14782 standard using a haze meter (NDH-5000W, Nippon Densho). The yellow index (YI) of the film sample was measured with a spectrophotometer (UltraScan PRO, Hunter Associates Laboratory) at 10° using a d65 light source in accordance with the ASTM-E313 standard. In addition, the transparent color of the film sample was measured using a spectrophotometer (CM3700A, Minolta) using a D65 light source. The results are shown in Table 4 below.

TABLE 4

| | Transmittance (%) | Haze (%) | YI | L* | a* | b* |
|---|---|---|---|---|---|---|
| Ex. A1 | 88.50 | 1.34 | 0.69 | 93.95 | −0.94 | 0.84 |
| Ex. A2 | 85.16 | 3.31 | 0.71 | 93.93 | −0.94 | 0.86 |
| C. Ex. A1 | 82.98 | 1.17 | 1.82 | 92.66 | −0.87 | 1.53 |
| C. Ex. A2 | 81.76 | 3.30 | 1.85 | 92.71 | −0.87 | 1.55 |
| C. Ex. A3 | 84.36 | 0.85 | 1.88 | 92.54 | −1.68 | 1.82 |

As can be seen from Table 4 above, the films of the Examples were excellent in all of transmittance, haze, and transparent color, whereas the films of the Comparative Examples were relatively poor in at least one of these characteristics.

### B. Laminate Film Comprising a Polyester-Based Film

Various laminate films comprising a polyester-based film were prepared and evaluated.

### Example B1

### Step (1) Formation of a Hard Coating Layer

A hard coating composition having a composition as shown in Table 5 below was coated on one side of a transparent polyester-based film (NRF, SKC) having a thickness of 50 μm by a die coating method. Thereafter, it was thermally treated at a temperature of 60° C. for 3 minutes to dry the solvent in the coating layer and cured by irradiating UV light at a dose of 1 J to prepare a hard coating layer having a thickness of about 5 μm.

TABLE 5

| | Component | % by weight |
|---|---|---|
| Solvent | Propylene glycol methyl ether | 22.5 |
| | Methyl isobutyl ketone | 52.5 |
| Binder | Urethane acrylate | 12.9 |
| | Acrylic ester | 3.8 |
| | Acrylate | 7.3 |
| Photoinitiator | 1-Hydroxycyclohexyl phenyl ketone | 0.8 |
| Antifouling additive | Perfluorohexylethyl acrylate | 0.2 |

### Step (2) Lamination of an Elastic Layer

A polyether-block-amide resin (Arkema Pebax™ Rnew™ 72R53, Arkema) was fed to an extruder, melt-blended at about 220° C., extruded to a single layer, and laminated with the base film on which the hard coating layer had been formed to prepare a laminate film with a PEBA layer having a thickness of 50 μm formed on the base film with the hard coating layer.

### Example B2

A laminate film was prepared in the same manner as in Example B1, except that a polyether-block-amide resin (Arkema Pebax™ Rnew™ 55R53, Arkema) was used to prepare a PEBA film in step (2) of Example B1.

### Comparative Example B1

A polyether-block-amide resin (Arkema Pebax™ Rnew™ 72R53, Arkema) was fed to an extruder, melt-blended at about 220° C., extruded to a single layer, and laminated with a transparent polyester-based film (NRF, SKC) having a thickness of 50 μm to prepare a laminate film with a PEBA layer having a thickness of 50 μm formed on the base film.

### Comparative Example B2

A laminate film was prepared in the same manner as in Comparative Example B1, except that a polyether-block-amide resin (Arkema Pebax™ Rnew™ 55R53, Arkema) was used to prepare a PEBA film.

The layer configuration of the films prepared above is summarized in Table 6 below.

TABLE 6

| | Layer configuration |
|---|---|
| Ex. B1 | Hard coating (5 μm) / NRF (50 μm) / PEBA 72R53 (50 μm) |
| Ex. B2 | Hard coating (5 μm) / NRF (50 μm) / PEBA 55R53 (50 μm) |
| C. Ex. B1 | NRF (50 μm) / PEBA 72R53 (50 μm) |
| C. Ex. B2 | NRF (50 μm) / PEBA 55R53 (50 μm) |

### Test Example B1: Nanoindentation Test

A nanoindentation test was performed on the film samples prepared in the Examples and Comparative Examples. Each film sample was cut into A4 size and stored at 25±5° C. and 50±5% RH until the test without additional pretreatment. Thereafter, each film sample was evaluated using a nanoindentation surface analyzer (FISCHERSCOPE HM2000, FISCHER). Specifically, each laminate film sample was placed on a glass test plate (Fischerscope Part no. 600-028) with a thickness of about 3T as a sample holder such that the surface of the hard coating layer (or the surface of the base film if there was no hard coating layer) was facing upward (i.e., to be the indentation side). Thereafter, the nanoindentation test was carried out in which a diamond tip was pressed downward for 15 seconds at a force of 30 mN at room temperature and held (crept) for five seconds; thereafter, it was raised upward. Martens hardness (HV), indentation modulus (E_{IT}), recovery relation (η_{IT}), indentation creep (C_{IT}), and maximum indentation depth (h_{max (at 30 mN)}) at a force of 30 mN), and recovery were measured. The nanoindentation test was carried out according to ISO 14577-1:2002(E) and 14577-2:2002(E). In addition, the recovery was calculated by the following equation.

$$Recovery ( \% ) = [ ( {h}_{m ax ( at 30 mN )} - {h}_{p} ) / {h}_{m ax ( at 30 mN )} ] \times 100$$

Here, h_{max (at 30 mN)} is the maximum indentation depth (μm) during which the surface of the hard coating layer was pressed downward for 15 seconds at a force of 30 mN and held (crept) for 5 seconds, and hₚ is the depth (μm) of the indentation that remained unrecovered even after the force was released.

The results are shown in Table 7 below.

### Test Example B2: Optical Properties

Each film sample was measured for average visible light transmittance according to the ISO 13468 standard using a haze meter (NDH-5000W, Nippon Densho). The results are shown in Table 7 below.

TABLE 7

| | | | | | | | Visible light |
|---|---|---|---|---|---|---|---|
| | HM | E_{IT} | η_{IT} | C_{IT} | h_{max (at 30 mN)} | Recovery | transmittance |
| | (N/mm²) | (MPa) | (%) | (%) | (μm) | (%) | (%) |
| Ex. B1 | 181.30 | 2962.57 | 63.811 | 4.272 | 2.6011 | 73.3987 | 89.9 |
| Ex. B2 | 186.99 | 2956.17 | 65.442 | 4.207 | 2.5597 | 74.1581 | 87.8 |
| C. Ex. B1 | 172.89 | 2964.41 | 60.076 | 3.372 | 2.6404 | 62.5125 | 83.2 |
| C. Ex. B2 | 173.82 | 2840.99 | 63.508 | 3.055 | 2.6251 | 64.3710 | 82.0 |

As can be seen from Table 7 above, the films of the Examples were excellent in all of the indentation test results (HM, E_{IT}, η_{IT}, and C_{IT}) and transmittance. Specifically, the films of the Examples had high hardness (HM) during indentation by virtue of the combination of a polyester film with a hard coating layer and a PEBA layer; thus, the indentation force could be distributed. They also had excellent recovery relation (η_{IT}) and good resistance to permanent deformation (E_{IT}) during indentation. As a result, the recovery was excellent despite the large indentation creep (C_{IT}); thus, the permanent deformation could be little even after folding. In addition, the films of the Examples had excellent transmittance; thus, they can be used as a cover window for mobile phones. In contrast, the films of the Comparative Examples were relatively poor in at least one of the test results.

1. A laminate film, which comprises a base film; a hard coating layer disposed on one side of the base film; and an elastic layer disposed on the other side of the base film, wherein the elastic layer comprises a polyether-block-amide.

2. The laminate film of claim 1, wherein the laminate film has a Vickers hardness (HV) of 48 N/mm² or more and an indentation hardness (H_{IT}) of 505 N/mm² or more when measured for the surface of the hard coating layer by a nanoindentation test according to the ISO 14577-1:2002(E) standard.

3. The laminate film of claim 1, wherein the laminate film has a recovery of 76% or more when measured for the surface of the hard coating layer by a nanoindentation test according to the ISO 14577-1:2002(E) standard, and the recovery is calculated by the following equation:
$$Recovery ( \% ) = [ ( {h}_{max ( at 30 mN )} - {h}_{p} ) / {h}_{max ( at 30 mN )} ] \times 100$$
wherein h_{max (at 30 mN)} is the maximum indentation depth (μm) during which the surface of the hard coating layer is pressed downward for 15 seconds at a force of 30 mN and held (crept) for 5 seconds, and hₚ is the depth (μm) of the indentation that remains unrecovered even after the force is released.

4. The laminate film of claim 1, wherein the laminate film has:
an average visible light transmittance of 80% or more when measured according to the ISO 13468 standard,
a haze of 4% or less when measured according to the ISO 14782 standard, and
a transmittance increase of 2% or more as calculated by the following equation:
$$Transmittance increase ( \% ) = TT 1 ( \% ) - TT 2 ( \% )$$
wherein TT1 is the average visible light transmittance (%) of the laminate film, TT2 is the average visible light transmittance (%) of a film having a layer structure excluding the hard coating layer from the laminate film, and the average visible light transmittance is measured under the same conditions according to the ISO 13468 standard.

5. The laminate film of claim 1, wherein the laminate film has a yellow index of 1.5 or less when measured at 10° using a D65 light source according to the ASTM-E313 standard and a yellow index decrease of 0.5 or more as calculated by the following equation:
$$Yellow index decrease = YI 2 - YI 1$$
wherein YI1 is the yellow index of the laminate film, YI2 is the yellow index of a film having a layer structure excluding the hard coating layer from the laminate film, and the yellow index is measured under the same conditions at 10° using a D65 light source according to the ASTM-E313 standard.

6. The laminate film of claim 1, wherein the laminate film has an L* value of 92 or more, an a* value of −2 to 1, and a b* value of −1 to 2 of transparent color in the CIE Lab color coordinates when measured using a D65 light source.

7. The laminate film of claim 1, wherein the base film comprises a polymer film or ultra-thin glass (UTG).

8. The laminate film of claim 1, wherein the base film comprises a polyester-based resin.

9. The laminate film of claim 8, wherein the laminate film has a Martens hardness (HM) of 175 N/mm² or more when measured for the surface of the hard coating layer by a nanoindentation test according to the ISO 14577-1:2002(E) standard.

10. The laminate film of claim 8, wherein the laminate film has an indentation modulus (E_{IT}) of 2,900 MPa or more when measured for the surface of the hard coating layer by a nanoindentation test according to the ISO 14577-1:2002(E) standard.

11. The laminate film of claim 8, wherein the laminate film has a recovery relation (η_{IT}) of 63.6% or more when measured for the surface of the hard coating layer by a nanoindentation test according to the ISO 14577-1:2002(E) standard.

12. The laminate film of claim 8, wherein the laminate film has an indentation creep (C_{IT}) of 3.5% or more when measured for the surface of the hard coating layer by a nanoindentation test according to the ISO 14577-1:2002(E) standard.

13. The laminate film of claim 8, wherein the laminate film has a recovery of 65% or more when measured for the surface of the hard coating layer by a nanoindentation test according to the ISO 14577-1:2002(E) standard, and the recovery is calculated by the following equation:
$$Recovery ( \% ) = [ ( {h}_{m ax ( at 30 mN )} - {h}_{p} ) / {h}_{m ax ( at 30 mN )} ] \times 100$$
wherein h_{max (at 30 mN)} is the maximum indentation depth (μm) during which the surface of the hard coating layer is pressed downward for 15 seconds at a force of 30 mN and held for 5 seconds, and hₚ is the depth (μm) of the indentation that remains unrecovered even after the force is released.

14. The laminate film of claim 8, wherein the laminate film has an average visible light transmittance of 85% or more when measured according to the ISO 13468 standard and a transmittance increase of 3% or more as calculated by the above equation:
$$Transmittance increase ( \% ) = TT 1 ( \% ) - TT 2 ( \% )$$
wherein TT1 is the average visible light transmittance (%) of the laminate film, TT2 is the average visible light transmittance (%) of a film having a layer structure excluding the hard coating layer from the laminate film, and the average visible light transmittance is measured under the same conditions according to the ISO 13468 standard.

15. The laminate film of claim 1, wherein the hard coating layer comprises at least one selected from the group consisting of a urethane acrylate-based compound, an acrylic ester-based compound, an acrylate-based compound, and an epoxy acrylate-based compound.

16. The laminate film of claim 15, wherein the hard coating layer further comprises a fluorine-based compound.

17. A display device, which comprises a display panel; and a cover window disposed on the front side of the display panel,
wherein the cover window comprises a base film; a hard coating layer disposed on one side of the base film; and an elastic layer disposed on the other side of the base film, and
the elastic layer comprises a polyether-block-amide.

18. The display device of claim 17, wherein the base film comprises a polyester-based resin.

19. The laminate film of claim 8, wherein the hard coating layer comprises at least one selected from the group consisting of a urethane acrylate-based compound, an acrylic ester-based compound, an acrylate-based compound, and an epoxy acrylate-based compound.
